(19) United States
(12) Patent Application Publication
(10) Pub. No.: US 2026/0259266 A1
(43) Pub. Date: Sep. 3, 2026

(54) ABNORMALITY DIAGNOSIS DEVICE AND ABNORMALITY DIAGNOSIS METHOD

(71) Applicant: Mitsubishi Electric Corporation, Tokyo (JP)

(72) Inventors: Ken HIRAKIDA, Tokyo (JP); Makoto KANEMARU, Tokyo (JP); Hiroshi INOUE, Tokyo (JP)

(73) Assignee: Mitsubishi Electric Corporation, Tokyo (JP)

(21) Appl. No.: 18/858,365

(22) PCT Filed: Apr. 18, 2023
(86) PCT No.: PCT/JP2023/015466

§ 371 Date: Oct. 21, 2024

(30) Foreign Application Priority Data
Apr. 26, 2022 (JP) 2022-072528

(51) Int. Cl. G01R 31/34; G01R 23/00

(52) U.S. Cl. CPC G01R 31/343; G01R 23/005

(57) ABSTRACT

An abnormality diagnosis device includes a frequency analysis section which performs frequency analysis on a waveform of the current signal of an electric motor, a feature frequency band extraction section which extracts data belonging to a feature frequency band so as to include a plurality of spectrum peaks, in a predetermined frequency range in a frequency analysis result, a feature quantity calculation section which detects the plurality of spectrum peaks from the data belonging to the feature frequency band, excludes data detected as the plurality of spectrum peaks from the data belonging to the feature frequency band, and calculates a sum of signal intensities included in the data belonging to the feature frequency band from which the above data have been excluded, and an abnormality diagnosis section which diagnoses that rotary machine equipment is abnormal in a case where the sum is equal to or greater than a threshold.

### TECHNICAL FIELD

The present disclosure relates to an abnormality diagnosis device, an abnormality diagnosis system, an abnormality diagnosis method, and a program.

### BACKGROUND ART

Conventionally, there have been various kinds of rotary machine equipment including an electric motor and load equipment such as a pump, a fan, and a blower using the electric motor as a power source. For example, abnormality diagnosis for the electric motor and the load equipment is performed by detecting a signal intensity that varies due to abnormality from a result of frequency analysis on driving current of the electric motor.

However, slight torque variation of the electric motor which occurs due to a failure mode such as cavitation in the pump or catching of a foreign material or air therein is unlikely to be periodic and thus is less likely to appear as a specific spectrum peak in a result of frequency analysis on the waveform of the driving current. Therefore, it has been difficult to diagnose abnormality due to a failure mode involving slight torque variation.

Accordingly, a method of diagnosing abnormality due to a failure mode involving slight torque variation is considered. For example, in an abnormality diagnosis device in Patent Document 1, driving current of an electric motor is subjected to frequency analysis, a fundamental component and harmonics are removed from a predetermined frequency range, and then a predetermined number of intensity values from the highest one in the frequency range are summed to calculate a deterioration degree, thus performing abnormality diagnosis for the electric motor in a case where abnormality due to cavitation has occurred.

### CITATION LIST

### Patent Document

Patent Document 1: Japanese Laid-Open Patent Publication No. 2020-153965

### SUMMARY OF THE INVENTION

### Problem to be Solved by the Invention

However, in the method in Patent Document 1, in a case where a failure mode other than cavitation or noise due to the influence of inverter driving has occurred at the same time as cavitation, a spectrum peak other than a fundamental component and harmonics arises in a predetermined frequency range, so that the spectrum peak is included in the sum of intensity values. Thus, accuracy of detection for slight torque variation is reduced, so that it is difficult to accurately diagnose abnormality due to a failure mode involving slight torque variation.

The present disclosure has been made to solve the above problem, and an object of the present disclosure is to provide an abnormality diagnosis device and the like that can accurately diagnose abnormality due to a failure mode involving slight torque variation.

### Means to Solve the Problem

An abnormality diagnosis device according to the present disclosure is an abnormality diagnosis device for diagnosing abnormality in rotary machine equipment and includes: a current signal storage section which stores a current signal of an electric motor; a frequency analysis section which performs frequency analysis on a waveform of the current signal stored in the current signal storage section; a feature frequency band extraction section which extracts data belonging to a feature frequency band so as to include a plurality of spectrum peaks, in a predetermined frequency range in a frequency analysis result which is a result of the frequency analysis on the waveform of the current signal performed by the frequency analysis section; a feature quantity calculation section which detects the plurality of spectrum peaks from the data belonging to the feature frequency band, excludes data detected as the plurality of spectrum peaks from the data belonging to the feature frequency band, and calculates a sum of signal intensities included in the data belonging to the feature frequency band from which the data detected as the plurality of spectrum peaks have been excluded; and an abnormality diagnosis section which diagnoses that the rotary machine equipment is abnormal in a case where the sum is equal to or greater than a first threshold.

Another abnormality diagnosis device according to the present disclosure is an abnormality diagnosis device for diagnosing abnormality in rotary machine equipment and includes: a current signal storage section which stores a current signal of an electric motor; a frequency analysis section which performs frequency analysis on a waveform of the current signal stored in the current signal storage section; a feature frequency band extraction section which extracts data belonging to a feature frequency band so as to include a plurality of spectrum peaks, in a predetermined frequency range in a frequency analysis result which is a result of the frequency analysis on the waveform of the current signal performed by the frequency analysis section; a feature quantity calculation section which sorts the data belonging to the feature frequency band in an intensity order of signal intensities, excludes data of the signal intensities equal to or greater than a second threshold from the data belonging to the feature frequency band, and calculates a sum of the signal intensities included in the data belonging to the feature frequency band from which the data of the signal intensities equal to or greater than the second threshold have been excluded; and an abnormality diagnosis section which diagnoses that the rotary machine equipment is abnormal in a case where the sum is equal to or greater than a first threshold.

An abnormality diagnosis system according to the present disclosure is an abnormality diagnosis system for diagnosing abnormality in rotary machine equipment and includes: a current signal storage section which stores a current signal of an electric motor; a frequency analysis section which performs frequency analysis on a waveform of the current signal stored in the current signal storage section; a feature frequency band extraction section which extracts data belonging to a feature frequency band so as to include a plurality of spectrum peaks, in a predetermined frequency range in a frequency analysis result which is a result of the frequency analysis on the waveform of the current signal performed by the frequency analysis section; a feature quantity calculation section which detects the plurality of spectrum peaks from the data belonging to the feature frequency band, excludes data detected as the plurality of spectrum peaks from the data belonging to the feature frequency band, and calculates a sum of signal intensities included in the data belonging to the feature frequency band from which the data detected as the plurality of spectrum peaks have been excluded; and an abnormality diagnosis section which diagnoses that the rotary machine equipment is abnormal in a case where the sum is equal to or greater than a first threshold.

Another abnormality diagnosis system according to the present disclosure is an abnormality diagnosis system for diagnosing abnormality in rotary machine equipment and includes: a current signal storage section which stores a current signal of an electric motor; a frequency analysis section which performs frequency analysis on a waveform of the current signal stored in the current signal storage section; a feature frequency band extraction section which extracts data belonging to a feature frequency band so as to include a plurality of spectrum peaks, in a predetermined frequency range in a frequency analysis result which is a result of the frequency analysis on the waveform of the current signal performed by the frequency analysis section; a feature quantity calculation section which sorts the data belonging to the feature frequency band in an intensity order of signal intensities, excludes data of the signal intensities equal to or greater than a second threshold from the data belonging to the feature frequency band, and calculates a sum of the signal intensities included in the data belonging to the feature frequency band from which the data of the signal intensities equal to or greater than the second threshold have been excluded; and an abnormality diagnosis section which diagnoses that the rotary machine equipment is abnormal in a case where the sum is equal to or greater than a first threshold.

An abnormality diagnosis method according to the present disclosure includes: a current signal detection step of detecting a current signal of current flowing through an electric motor; a frequency analysis step of performing frequency analysis on a waveform of the current signal detected in the current signal detection step; a feature frequency band extraction step of extracting data belonging to a feature frequency band so as to include a plurality of spectrum peaks, in a predetermined frequency range in a frequency analysis result which is a result of the frequency analysis on the waveform of the current signal performed in the frequency analysis step; a data exclusion step of detecting the plurality of spectrum peaks from the data belonging to the feature frequency band, and excluding data detected as the plurality of spectrum peaks from the data belonging to the feature frequency band; a feature quantity calculation step of calculating a sum of signal intensities included in the data belonging to the feature frequency band from which the data detected as the plurality of spectrum peaks have been excluded; a determination step of determining whether or not the sum is equal to or greater than a first threshold; and an abnormality diagnosis step of diagnosing that rotary machine equipment is abnormal in a case where the sum is equal to or greater than the first threshold.

Another abnormality diagnosis method according to the present disclosure is an abnormality diagnosis method for diagnosing abnormality in rotary machine equipment and includes: a current signal detection step of detecting a current signal of current flowing through an electric motor; a frequency analysis step of performing frequency analysis on a waveform of the current signal detected in the current signal detection step; a feature frequency band extraction step of extracting data belonging to a feature frequency band so as to include a plurality of spectrum peaks, in a predetermined frequency range in a frequency analysis result which is a result of the frequency analysis on the waveform of the current signal performed in the frequency analysis step; a data exclusion step of sorting the data belonging to the feature frequency band in an intensity order of signal intensities, and excluding data of the signal intensities equal to or greater than a second threshold from the data belonging to the feature frequency band; a feature quantity calculation step of calculating a sum of the signal intensities included in the data belonging to the feature frequency band from which the data of the signal intensities equal to or greater than the second threshold have been excluded; a determination step of determining whether or not the sum is equal to or greater than a first threshold; and an abnormality diagnosis step of diagnosing that the rotary machine equipment is abnormal in a case where the sum is equal to or greater than the first threshold.

A program according to the present disclosure is a program for diagnosing abnormality in rotary machine equipment and causes a computer to execute: a current signal detection step of detecting a current signal of current flowing through an electric motor; a frequency analysis step of performing frequency analysis on a waveform of the current signal detected in the current signal detection step; a feature frequency band extraction step of extracting data belonging to a feature frequency band so as to include a plurality of spectrum peaks, in a predetermined frequency range in a frequency analysis result which is a result of the frequency analysis on the waveform of the current signal performed in the frequency analysis step; a data exclusion step of detecting the plurality of spectrum peaks from the data belonging to the feature frequency band, and excluding data detected as the plurality of spectrum peaks from the data belonging to the feature frequency band; a feature quantity calculation step of calculating a sum of signal intensities included in the data belonging to the feature frequency band from which the data detected as the plurality of spectrum peaks have been excluded; a determination step of determining whether or not the sum is equal to or greater than a first threshold; and an abnormality diagnosis step of diagnosing that the rotary machine equipment is abnormal in a case where the sum is equal to or greater than the first threshold.

Another program according to the present disclosure is a program for diagnosing abnormality in rotary machine equipment and causes a computer to execute: a current signal detection step of detecting a current signal of current flowing through an electric motor; a frequency analysis step of performing frequency analysis on a waveform of the current signal detected in the current signal detection step; a feature frequency band extraction step of extracting data belonging to a feature frequency band so as to include a plurality of spectrum peaks, in a predetermined frequency range in a frequency analysis result which is a result of the frequency analysis on the waveform of the current signal performed in the frequency analysis step; a data exclusion step of detecting the plurality of spectrum peaks from the data belonging to the feature frequency band, and excluding data detected as the plurality of spectrum peaks from the data belonging to the feature frequency band; a feature quantity calculation step of calculating a sum of signal intensities included in the data belonging to the feature frequency band from which the data detected as the plurality of spectrum peaks have been excluded; a determination step of determining whether or not the sum is equal to or greater than a first threshold; and an abnormality diagnosis step of diagnosing that the rotary machine equipment is abnormal in a case where the sum is equal to or greater than the first threshold.

### Effect of the Invention

According to the present disclosure, it is possible to accurately diagnose abnormality due to a failure mode involving slight torque variation.

### BRIEF DESCRIPTION OF THE DRAWINGS

FIG. 1 shows a schematic configuration of an abnormality diagnosis device according to embodiment 1.

FIG. 2 shows a schematic configuration of the abnormality diagnosis device according to embodiment 1.

FIG. 3 shows a schematic configuration of a diagnosis result output section according to embodiment 1.

FIG. 4 shows a hardware configuration of a monitoring diagnosis section according to embodiment 1.

FIG. 5 is a flowchart showing a processing flow in the abnormality diagnosis device according to embodiment 1.

FIG. 6 shows an example of the waveform of a current signal measured by a current detection section according to embodiment 1.

FIG. 7 shows an example of a frequency analysis result for a current signal measured by the current detection section according to embodiment 1.

FIG. 8 shows an example of a frequency analysis result for a current signal measured by the current detection section according to embodiment 1.

FIG. 9 shows an example of a frequency analysis result for a current signal measured by the current detection section according to embodiment 1.

FIG. 10 shows another schematic configuration of the abnormality diagnosis device according to embodiment 1.

FIG. 11 shows another schematic configuration of the abnormality diagnosis device according to embodiment 1.

FIG. 12 is a schematic configuration diagram of a circuit shown in FIG. 11.

FIG. 13 shows a schematic configuration of an abnormality diagnosis system according to modification 1 of embodiment 1.

FIG. 14 shows a schematic configuration of an abnormality diagnosis system according to modification 2 of embodiment 1.

FIG. 15 shows a schematic configuration of an abnormality diagnosis device according to embodiment 2.

FIG. 16 is a flowchart showing a processing flow in the abnormality diagnosis device according to embodiment 2.

FIG. 17 shows an example of a frequency analysis result for a current signal measured by a current detection section according to embodiment 2.

FIG. 18 shows an example of sorted data according to embodiment 2.

FIG. 19 shows a schematic configuration of an abnormality diagnosis system according to modification 1 of embodiment 2.

FIG. 20 shows a schematic configuration of an abnormality diagnosis system according to modification 2 of embodiment 2.

FIG. 21 shows a schematic configuration of an abnormality diagnosis device according to embodiment 3.

FIG. 22 is a flowchart showing a processing flow in the abnormality diagnosis device according to embodiment 3.

FIG. 23 shows a schematic configuration of an abnormality diagnosis device according to embodiment 4.

FIG. 24 is a flowchart showing a processing flow in an abnormality diagnosis device according to embodiment 4.

FIG. 25 shows a schematic configuration of an abnormality diagnosis device according to embodiment 5.

FIG. 26 is a flowchart showing a processing flow in an abnormality diagnosis device according to embodiment 5.

### DESCRIPTION OF EMBODIMENTS

Hereinafter, embodiments of the present disclosure will be described with reference to the accompanying drawings. The drawings are schematically shown, and the mutual relationships of sizes and positions of parts shown in different drawings are not necessarily accurately expressed and may be changed as appropriate. In the following description and the drawings, the same components are denoted by the same reference characters, and the names and the functions thereof are the same or similar. Therefore, the detailed description of such components may be omitted.

### Embodiment 1

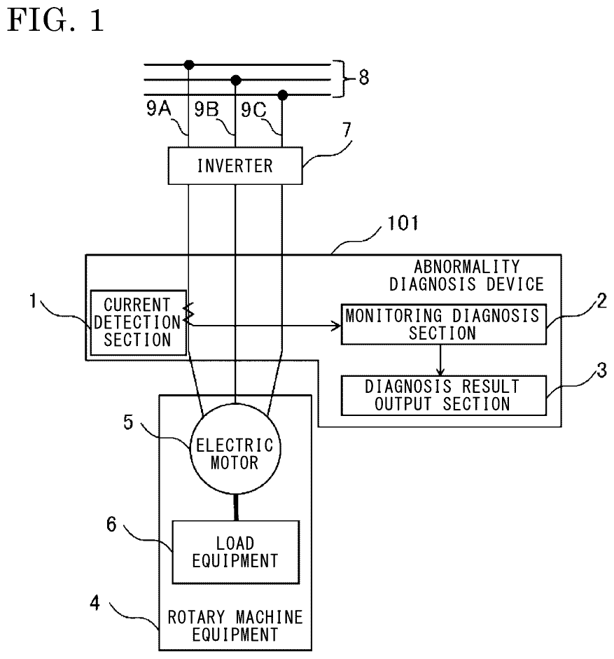

With reference to FIG. 1 to FIG. 9, an abnormality diagnosis device 101 according to the present embodiment will be described.

In FIG. 1, the abnormality diagnosis device 101 includes a current detection section 1 connected to any of wires 9A, 9B, 9C connected to an electric motor 5, a monitoring diagnosis section 2, and a diagnosis result output section 3.

The current detection section 1 measures current flowing through the wire 9A, 9B, 9C, thus acquiring driving current for driving the electric motor 5. The current detection section 1 outputs the acquired driving current as a current signal to the monitoring diagnosis section 2. The monitoring diagnosis section 2 performs determination for abnormality in the rotary machine equipment 4. After determination for abnormality in the rotary machine equipment 4, the monitoring diagnosis section 2 sends the determination result to the diagnosis result output section 3. The diagnosis result output section 3 notifies a monitoring person about whether or not there is abnormality.

The electric motor 5 is a three-phase AC motor. The electric motor 5 is connected to a commercial power supply 8 via an inverter 7 and is driven by the inverter 7.

The inverter 7 is connected to the commercial power supply 8 and is formed by combination of an AC-DC converter which converts AC power from the commercial power supply 8 to DC power and a DC-AC converter which converts DC power to AC power. The inverter 7 supplies the AC power converted by the DC-AC converter, to the electric motor 5.

The rotary machine equipment 4 includes the electric motor 5 and load equipment 6 which is connected to the electric motor 5 and uses the electric motor 5 as a power source. For example, the load equipment 6 is a water pump, a vacuum pump, a fan, a blower, etc., driven with the electric motor 5 as a power source.

As an example, a case where the abnormality diagnosis device 101 is applied to a public plant monitoring control system represented by a water treatment plant such as a water purification plant or a sewage treatment plant, will be described. The load equipment 6 such as a water intake pump or a water feeding pump used in a water treatment plant is driven by the electric motor 5. The abnormality diagnosis device 101 performs abnormality diagnosis for the rotary machine equipment 4 including the load equipment 6 and the electric motor 5, in the monitoring diagnosis section 2, using the current signal acquired from the current detection section 1 connected to any of the wires 9A, 9B, 9C connected to the electric motor 5. A result of abnormality determination for the rotary machine equipment 4 by the monitoring diagnosis section 2 is sent to the diagnosis result output section 3 to notify an operation management person for the water treatment plant about whether or not there is abnormality.

In the present embodiment, the rotary machine equipment 4 includes the electric motor 5 driven by the inverter 7 and the water pump which is the load equipment 6, and an example in which a current signal inputted from the current detection section 1 is analyzed to diagnose abnormality due to cavitation of the water pump involving slight torque variation will be described.

The cavitation is a phenomenon in which, when the pressure of a liquid is lowered, the liquid is vaporized to produce bubbles. After bubbles are produced, if the liquid has recovered to be no longer in the low-pressure state, the produced bubbles disappear with a great shock. Thus, when cavitation occurs in the water pump, the produced bubbles obstruct flow of the liquid in the water pump, so that the pumping-up performance of the water pump is lowered. In addition, when cavitation disappears in the water pump, abnormality such as damage of the water pump or formation of a through hole might be caused by a shock due to disappearance of the bubbles.

In the present embodiment, the example in which the current detection section 1 is connected to any wire of the commercial power supply 8 connected to the electric motor 5 has been shown, but the current detection section 1 may be provided for each phase of the commercial power supply 8. Even in this case, it suffices that any of the phases is measured.

In the present embodiment, the example in which abnormality due to cavitation of the water pump involving slight torque variation has been shown, but abnormality due to a failure mode other than cavitation of the water pump and involving slight torque variation may be detected. Examples of such failure modes other than cavitation of the water pump include catching of a foreign material in the water pump, catching of air in the water pump, deposition of a by-product in a vacuum pump, wear of a bearing, and breakage of a blade of a fan.

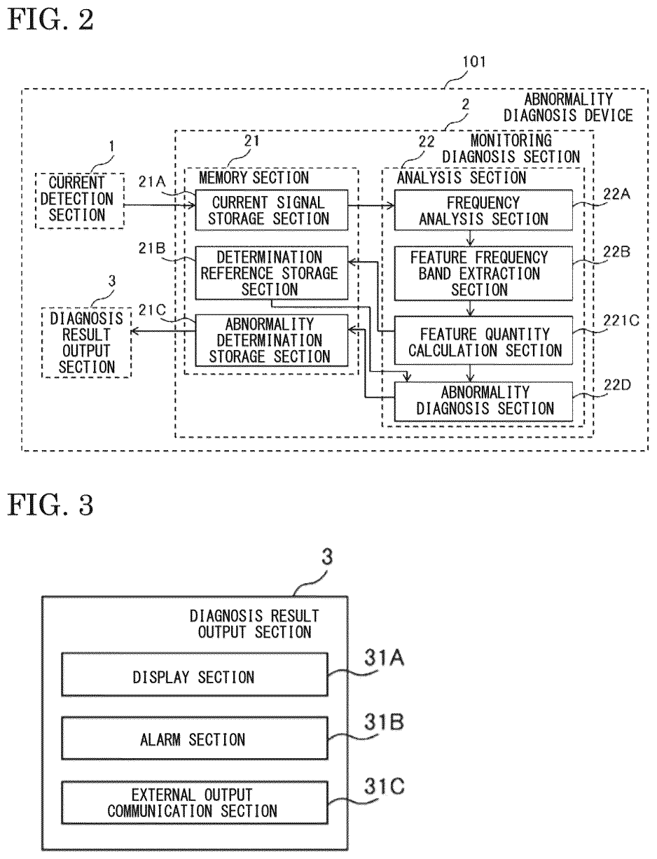

In FIG. 2, the monitoring diagnosis section 2 includes a memory section 21 and an analysis section 22. The memory section 21 includes a current signal storage section 21A, a determination reference storage section 21B, and an abnormality determination storage section 21C. The analysis section 22 includes a frequency analysis section 22A, a feature frequency band extraction section 22B, a feature quantity calculation section 221C, and an abnormality diagnosis section 22D. In FIG. 3, the diagnosis result output section 3 includes a display section 31A, an alarm section 31B, and an external output communication section 31C.

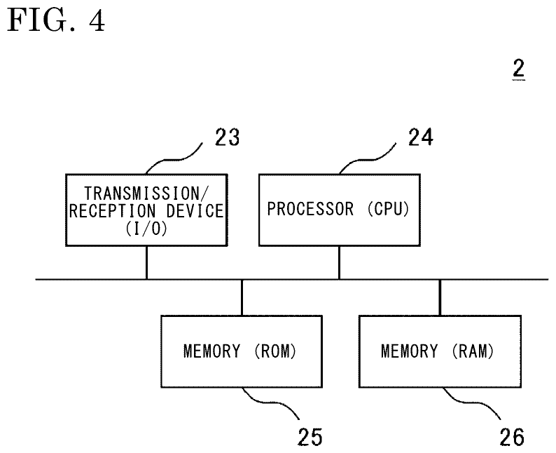

FIG. 4 shows a hardware configuration of the monitoring diagnosis section 2 in the present embodiment. The monitoring diagnosis section 2 includes a transmission/reception device 23, a processor (central processing unit (CPU)) 24, a memory (read only memory (ROM)) 25, and a memory (random access memory (RAM)) 26. In the monitoring diagnosis section 2, the processor 24 executes a program stored in the memory 25 in advance, to diagnose abnormality in the rotary machine equipment 4, and thus a diagnosis result is outputted.

In the monitoring diagnosis section 2, various function modules are implemented by the processor 24 executing a predetermined program stored in the memory 25. The function modules include the analysis section 22. The memory section 21 is included in the memory 25 and the memory 26. The transmission/reception device 23 transmits/receives signals to/from the current detection section 1 connected to the monitoring diagnosis section 2 and to/from the diagnosis result output section 3 connected to the monitoring diagnosis section 2.

Each function module of the monitoring diagnosis section 2 may be implemented by the processor 24 executing software processing in accordance with a predetermined program as described above, or for some of the function modules, predetermined numerical and logic operation processing may be executed by hardware such as an electronic circuit having a function corresponding to each function module.

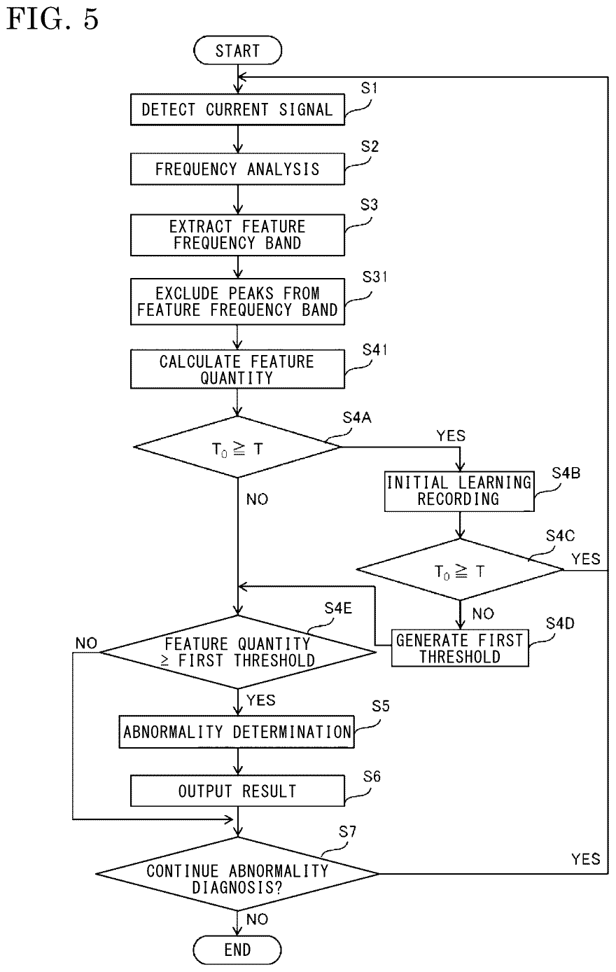

With reference to FIG. 5, a processing flow in the abnormality diagnosis device 101 according to the present embodiment will be described together with the detailed description of each component included in the abnormality diagnosis device 101. The flowchart formed of the steps shown below is repeatedly executed every time a predetermined condition is satisfied.

In step S1, the current detection section 1 measures current flowing through the electric motor 5 and outputs a current signal to the current signal storage section 21A. The current signal storage section 21A stores the current signal.

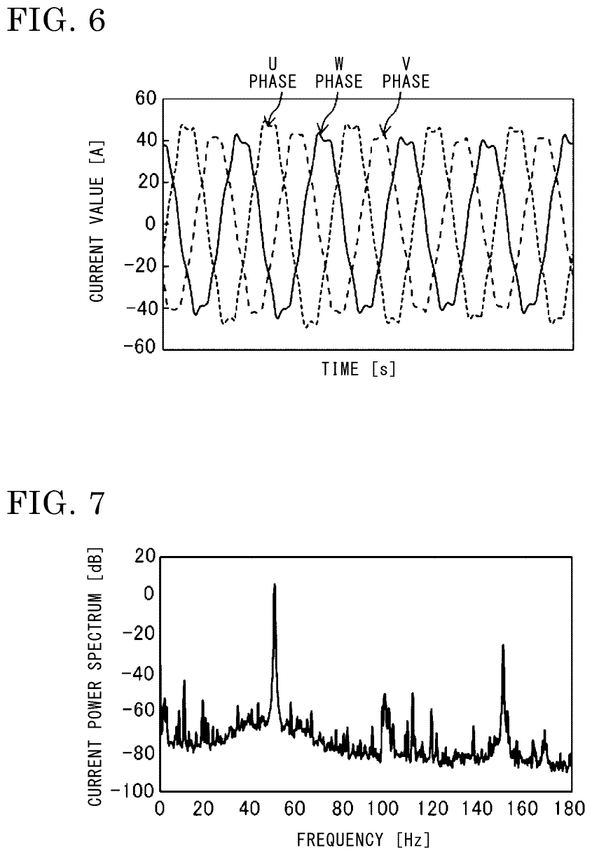

FIG. 6 shows the waveform of the current signal detected by the current detection section 1. The vertical axis indicates a current value, and the horizontal axis indicates time. In the waveform of the current signal, a dotted line represents U phase, a broken line represents V phase, and a solid line represents W phase.

Then, in step S2, the frequency analysis section 22A performs frequency analysis on the waveform of the current signal acquired from the current signal storage section 21A.

FIG. 7 shows a frequency analysis result for the waveform of the current signal for U phase shown by the dotted line in FIG. 6. The vertical axis indicates a current power spectrum, and the horizontal axis indicates a frequency. The frequency analysis result shown in FIG. 7 is a result in a case where a power supply frequency is 50 Hz, and has spectrum peaks at 50 Hz which is the power supply frequency and 150 Hz which is a third-order component with respect to the power supply frequency.

The power supply frequency is the frequency of the commercial power supply 8, and the third-order component with respect to the power supply frequency is a frequency that is three times the power supply frequency. When a frequency is x times the power supply frequency, the frequency is expressed as an xth-order component with respect to the power supply frequency. Here, x is an integer not less than 0.

Here, a reason why the frequency analysis result shown in FIG. 7 has spectrum peaks at the power supply frequency and the third-order component with respect to the power supply frequency, will be described.

In a process of power conversion by the inverter 7, when AC power from the commercial power supply 8 is converted to DC power by the AC-DC converter, current having a distorted waveform in which a fundamental component having the power supply frequency and harmonics having frequencies that are integer multiples of the power supply frequency are combined is generated through converter circuit operation. The current having the distorted waveform influences the voltage waveform so as to distort the voltage waveform. Also in a device to which the voltage having the distorted waveform is applied, current having a similarly distorted waveform flows.

For the above reason, the frequency analysis result shown in FIG. 7 has spectrum peaks at the power supply frequency and the third-order component with respect to the power supply frequency. In the present embodiment, the example in which the waveform of the current signal for U phase is subjected to frequency analysis has been shown, but a current signal for another single phase, current signals for a plurality of phases, or current signals for all phases may be subjected to frequency analysis.

The example in which the power supply frequency is 50 Hz is shown in FIG. 7, but in the following description of the processing flow in the abnormality diagnosis device 101, the processing flow in a case where the power supply frequency is 60 Hz will be described.

Then, in step S3 in FIG. 5, the feature frequency band extraction section 22B extracts data belonging to a feature frequency band so as to include a plurality of spectrum peaks, in a predetermined frequency range. In the present embodiment, data belonging to a feature frequency band are extracted so as to include a plurality of spectrum peaks, in a frequency range from a zeroth-order component to a second-order component with respect to the power supply frequency.

Specifically, in data of the frequency analysis result for the current signal for U phase inputted from the frequency analysis section 22A, a frequency range from 0 Hz which is a zeroth-order component to 120 Hz which is a second-order component with respect to the power supply frequency is set as a feature frequency band, and data belonging to the feature frequency band are extracted.

Here, the feature frequency band is a frequency range to be used for calculation of a feature quantity described later.

Next, a reason why the frequency range from the zeroth-order component to the second-order component with respect to the power supply frequency is set as the feature frequency band and data belonging to the feature frequency band are extracted, will be described. In a case where cavitation occurs in the load equipment 6, torque of the electric motor 5 required for driving the load equipment 6 slightly varies as compared to a case where cavitation does not occur. Since torque of the electric motor 5 is determined by the current value, slight variation in torque of the electric motor 5 influences the driving current for the electric motor 5.

Thus, in the frequency analysis result for the current signal influenced by the slight torque variation, the signal intensity increases in the frequency range from the zeroth-order component to the second-order component with respect to the power supply frequency, which is a frequency range around the power supply frequency.

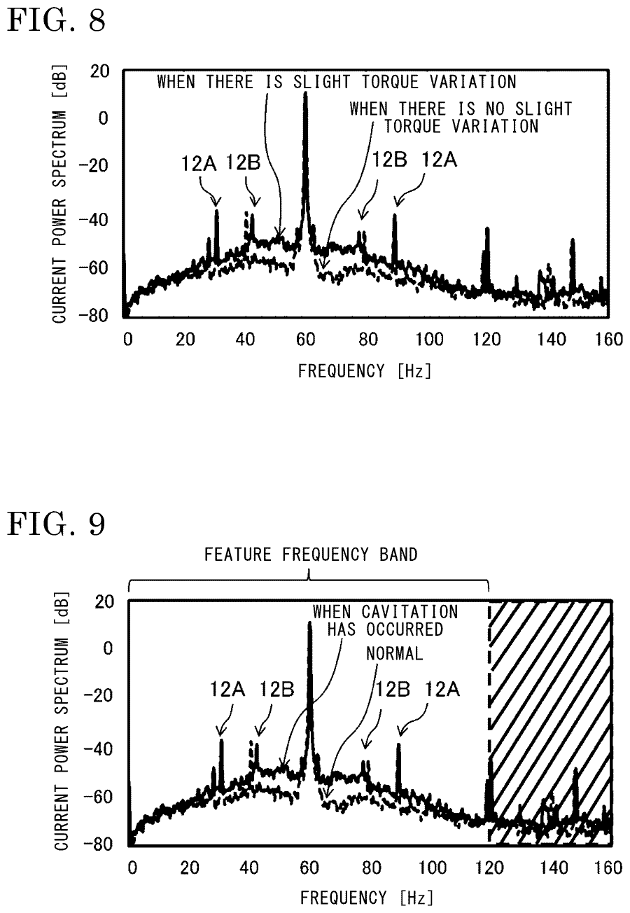

FIG. 8 shows an example of a graph in which frequency analysis results for current signals in a case where there is slight torque variation in the load equipment 6 and a case where there is no slight torque variation are compared. The vertical axis indicates a current power spectrum, and the horizontal axis indicates a frequency. A solid line represents a case where there is slight torque variation, and a dotted line represents a case where there is no slight torque variation. The power supply frequency is 60 Hz, and the rotational frequency of the electric motor 5 is 30 Hz. The rotational frequency is a value when the rotational speed of the electric motor 5 is expressed as a frequency.

As shown by the solid line, it can be confirmed that the signal intensity in the case where there is slight torque variation increases in a frequency range of ±40 Hz from the power supply frequency toward a low-frequency side and a high-frequency side centered at 60 Hz which is the power supply frequency, i.e., a frequency range of 20 Hz to 100 Hz, as compared to the case where there is no slight torque variation.

For the above reason, the frequency range from 0 Hz which is the zeroth-order component to 120 Hz which is the second-order component with respect to the power supply frequency is extracted as the feature frequency band.

While FIG. 8 shows the influence of slight torque variation in the frequency range from the zeroth-order component to the second-order component with respect to the power supply frequency which is a frequency range around the power supply frequency, slight torque variation has an influence also in a frequency range from a fourth-order component to a sixth-order component with respect to the power supply frequency which is a frequency range around a fifth-order component with respect to the power supply frequency, and a frequency range from a sixth-order component to an eighth-order component with respect to the power supply frequency which is a frequency range around a seventh-order component with respect to the power supply frequency.

In addition, as shown in FIG. 8, in the frequency range from the zeroth-order component to the second-order component with respect to the power supply frequency, a plurality of spectrum peaks appear on both sides of the power supply frequency. In FIG. 8, at frequencies defined as (power supply frequency±rotational frequency), i.e., 30 Hz and 90 Hz, a spectrum 12A of sideband components of a modulation wave described later appears as spectrum peaks. In addition, at frequencies defined as (power supply frequency ±20 Hz), i. e., 40 Hz and 80 Hz, a spectrum 12B of noise components due to switching operation of the inverter 7 described later appears as spectrum peaks.

The modulation wave is one of elements used in pulse width modulation (PWM) control which is a power control method for a DC-AC inverter. Here, the modulation wave is a fundamental component, and the modulation wave frequency which is the frequency of the modulation wave corresponds to the power supply frequency.

The sideband components of the modulation wave depend on the rotational frequency of the electric motor 5, and appear at frequencies shifted by the rotational frequency toward both sides of the modulation wave frequency. In FIG. 8, the spectrum 12A of the sideband components of the modulation wave appears at frequencies defined as (power supply frequency±rotational frequency).

Regarding the noise component due to switching operation of the inverter 7, in a process of power conversion by the inverter 7, when DC power is converted to AC power by the DC-AC inverter, DC voltage outputted from the AC-DC converter and AC voltage outputted to the electric motor 5 slightly vary at the power supply frequency and frequencies that are integer multiples of the power supply frequency, through switching operation of the inverter circuit. The slightly varying values appear as a spectrum 12B of noise components due to switching operation of the inverter 7.

Although the spectrum 12B of noise components appears at ±20 Hz with respect to the power supply frequency in FIG. 8, such noise components may appear at frequencies different from (power supply frequency ±20 Hz), depending on the control method, the type, or the like of the inverter 7 to be used.

The spectrum 12A of sideband components of the modulation wave and the spectrum 12B of noise components due to switching operation of the inverter 7 are examples of noise caused due to inverter driving.

In the above description, the example in which the spectrum 12A of sideband components and the spectrum 12B of noise components appear in the frequency range from the zeroth-order component to the second-order component with respect to the power supply frequency, has been shown. However, in a case where abnormality other than cavitation also has occurred at the same time, spectrum peaks different from the spectrum 12A of sideband components and the spectrum 12B of noise components may appear in the frequency range.

In the above description, the example in which data belonging to the feature frequency band are extracted so as to include a plurality of spectrum peaks, in the frequency range from the zeroth-order component to the second-order component with respect to the power supply frequency, has been shown. However, without limitation thereto, data belonging to the feature frequency band may be extracted so as to include a plurality of spectrum peaks, in a frequency range from the fourth-order component to the sixth-order component with respect to the power supply frequency, a frequency range from the sixth-order component to the eighth-order component with respect to the power supply frequency, or the like.

For example, data belonging to the feature frequency band may be extracted so as to include a plurality of spectrum peaks, in a frequency range from 0 Hz to 120 Hz, a frequency range from 200 Hz to 360 Hz, a frequency range from 300 Hz to 480 Hz, or the like, so that a case where the power supply frequency is 50 Hz and a case where the power supply frequency is 60 Hz are both covered.

FIG. 9 shows a case where data belonging to the feature frequency band, i.e., the frequency range of 0 to 120 Hz, are extracted from the comparison graph of the frequency analysis results for the current signals shown in FIG. 8.

In step S3 in FIG. 5, the feature frequency band extraction section 22B extracts data belonging to the feature frequency band as shown in FIG. 9, from data of the frequency analysis result for the current signal for U phase inputted from the frequency analysis section 22A.

In step S31 in FIG. 5, the feature quantity calculation section 221C detects and excludes, as spectrum peaks, a spectrum of the power supply frequency, a spectrum of the second-order component with respect to the power supply frequency, the spectrum 12A of sideband components, and the spectrum 12B of noise components, from data belonging to the feature frequency band inputted from the feature frequency band extraction section 22B.

As an example of a detection method for spectrum peaks, a predetermined number of data from the one having the highest signal intensity among data belonging to the feature frequency band may be detected as spectrum peaks. As another example, the feature frequency band is divided at predetermined frequency intervals, and an average value of signal intensities in each of the divided ranges is taken. Then, signal intensities in each of the divided ranges are compared with the average value, and data of signal intensities greater than the average value are detected as spectrum peaks.

In a case where step S31 is applied to data belonging to the feature frequency band in FIG. 9, the spectrum of the power supply frequency, the spectrum of the second-order component with respect to the power supply frequency, the spectrum 12A of sideband components, and the spectrum 12B of noise components, are detected and excluded as spectrum peaks, from the data belonging to the feature frequency band.

In the present embodiment, the example in which the spectrum 12A sideband components and the spectrum 12B of noise components are excluded from data belonging to the feature frequency band, has been shown. Meanwhile, in a case where a spectrum peak other than the spectrum 12A of sideband components and the spectrum 12B of noise components appears in the feature frequency band, the spectrum peak other than the spectrum 12A of sideband components and the spectrum 12B of noise components is similarly excluded. That is, spectrum peaks appearing in the feature frequency band are excluded so as not to be used in diagnosis for abnormality due to a failure mode involving slight torque variation.

Here, a reason why spectrum peaks are excluded from data belonging to the feature frequency band in step S31 in FIG. 5 will be described. As shown in FIG. 8, in a case where there is slight torque variation, the current signal influenced by the slight torque variation has such a frequency characteristic that the signal intensity increases in a frequency range of ±40 Hz from the power supply frequency. Meanwhile, since current change due to slight torque variation is slight, increase in the signal intensity in the feature frequency band is also slight as compared to the spectrum peaks. Here, if the spectrum peaks are included in data belonging to the feature frequency band, the slight change in the signal intensity might be buried among the spectrum peaks. For this reason, spectrum peaks are excluded from data belonging to the feature frequency band in step S31.

Then, in step S41 in FIG. 5, the feature quantity calculation section 221C calculates a feature quantity from data belonging to the feature frequency band from which spectrum peaks have been excluded. The feature quantity can be obtained by calculating the sum of all signal intensities included in the data belonging to the feature frequency band from which spectrum peaks have been excluded. That is, in the present embodiment, the feature quantity is the sum of all signal intensities included in data belonging to the feature frequency band from which spectrum peaks have been excluded.

Here, the signal intensities are current values or a current power spectrum. In FIG. 9, the feature quantity corresponds to the sum of all current power spectra included in data belonging to the feature frequency band from which spectrum peaks have been excluded.

Then, in step S4A in FIG. 5, with an initial learning recording period denoted by T and a predetermined period denoted by T₀, the feature quantity calculation section 221C determines whether or not the initial learning recording period T is smaller than the predetermined period T₀.

Here, initial learning recording means that, in a predetermined period from the start of driving of the rotary machine equipment 4, the feature quantity is calculated in step S41 and the calculated feature quantity is accumulated in the determination reference storage section 21B. The initial learning recording period is a predetermined period in which the initial learning recording is repeatedly executed for generating a determination reference described later.

If the initial learning recording period T is smaller than the predetermined period T₀ (YES in step S4A), the process proceeds to step S4B. If the initial learning recording period T is equal to or greater than the predetermined period T₀ (NO in step S4A), the process proceeds to step S4E. Specifically, a case where the initial learning recording period T is smaller than the predetermined period T₀ corresponds to a state within the initial learning recording period from the start of driving of the rotary machine equipment 4, and a case where the initial learning recording period T is equal to or greater than the predetermined period T₀ corresponds to a period in which the abnormality diagnosis device 101 performs abnormality diagnosis for the rotary machine equipment 4 after the initial learning recording period has ended.

Then, in step S4B, the feature quantity calculation section 221C accumulates the feature quantity in the determination reference storage section 21B, thus performing initial learning recording.

Then, in step S4C, the feature quantity calculation section 221C determines whether or not the initial learning recording period T is smaller than the predetermined period T₀. If the initial learning recording period T is smaller than the predetermined period T₀ (YES in step S4C), the process proceeds to step S1. If the initial learning recording period T is equal to or greater than the predetermined period T₀ (NO in step S4C), the process proceeds to step S4D.

Then, in step S4D, the feature quantity calculation section 221C performs statistical processing on the feature quantities accumulated in the determination reference storage section 21B during the predetermined period T₀ from the start of driving of the rotary machine equipment 4 through the initial learning recording, thereby generating a determination reference which is a first threshold, and stores the generated determination reference in the determination reference storage section 21B.

As an example of a statistical processing method for generating the determination reference, the determination reference may be generated by calculating the average, a dispersion σ, 2σ, 3σ, or the like of the feature quantities accumulated in the determination reference storage section 21B.

Then, in step S4E, the abnormality diagnosis section 22D determines whether or not the feature quantity is equal to or greater than the first threshold. If the feature quantity is equal to or greater than the first threshold (YES in step S4E), the process proceeds to step S5. If the feature quantity is smaller than the first threshold (NO in step S4E), the process proceeds to step S7.

Then, in step S5, the abnormality diagnosis section 22D diagnoses that the rotary machine equipment 4 is abnormal, and outputs the diagnosis result to the abnormality determination storage section 21C.

Here, in the feature quantity calculation section 221C, in a case where the number of data of the determination reference generated through the initial learning and the number of data of the feature quantity are different from each other, comparison between the determination reference and the feature quantity cannot be performed accurately, and therefore processing for equalizing the number of data of the determination reference and the number of data of the feature quantity is performed. If the number of data of the determination reference is larger than the number of data of the feature quantity, data having higher signal intensities are sequentially excluded from data of the determination reference so that the number of data of the determination reference and the number of data of the feature quantity coincide with each other. If the number of data of the determination reference is smaller than the number of data of the feature quantity, data having higher signal intensities are sequentially excluded from data of the feature quantity so that the number of data of the feature quantity and the number of data of the determination reference coincide with each other.

As an example of such a case where the number of data of the determination reference and the number of data of the feature quantity are different from each other, there is a case where the resolution of frequency analysis is the same but the frequency range of the feature frequency band for extracting data belonging to the feature frequency band is different.

Then, in step S6, the diagnosis result output section 3 acquires a diagnosis result from the abnormality determination storage section 21C. Accordingly, the diagnosis result output section 3 displays the diagnosis result on the display section 31A such as a display, the alarm section 31B issues an alarm by, for example, emitting an alarm sound or lighting up or blinking an abnormality lamp, in a case where the rotary machine equipment 4 is diagnosed as abnormal, and the external output communication section 31C transmits the diagnosis result to an external device such as a control device panel, a personal computer (PC), or a cloud server.

Then, in step S7, the abnormality diagnosis section 22D determines whether or not to continue abnormality diagnosis. If abnormality diagnosis is continued (YES in step S7), the process proceeds to step S1. If abnormality diagnosis is not continued (NO in step S7), the process is ended.

As an example of a method for determining whether or not to continue abnormality diagnosis, a period in which abnormality diagnosis is continued may be set in advance for the abnormality diagnosis section 22D, and if the period in which abnormality diagnosis is continued is exceeded, it may be determined that abnormality diagnosis is not continued. The period in which abnormality diagnosis is continued is, for example, a period in which the rotary machine equipment 4 is operated.

As described above, abnormality in the rotary machine equipment 4 is diagnosed through step S1 to step S7 in FIG. 5.

As described above, in the abnormality diagnosis device 101 of the present embodiment, the sum of all signal intensities included in data belonging to the feature frequency band from which data detected as spectrum peaks have been excluded, is compared with the first threshold, whereby abnormality diagnosis for the rotary machine equipment 4 is performed. Thus, slight change in signal intensities due to slight torque variation is prevented from being buried among spectrum peaks, whereby detection accuracy for slight torque variation is improved, and as a result, abnormality due to a failure mode involving slight torque variation can be accurately diagnosed.

As described above, the abnormality diagnosis device 101 of the present embodiment is an abnormality diagnosis device 101 for diagnosing abnormality in the rotary machine equipment 4 and includes: a current signal storage section 21A which stores a current signal of an electric motor 5; a frequency analysis section 22A which performs frequency analysis on a waveform of the current signal stored in the current signal storage section 21A; a feature frequency band extraction section 22B which extracts data belonging to a feature frequency band so as to include a plurality of spectrum peaks, in a predetermined frequency range in a frequency analysis result which is a result of the frequency analysis on the waveform of the current signal performed by the frequency analysis section 22A; a feature quantity calculation section 221C which detects the plurality of spectrum peaks from the data belonging to the feature frequency band, excludes data detected as the plurality of spectrum peaks from the data belonging to the feature frequency band, and calculates a sum of signal intensities included in the data belonging to the feature frequency band from which the data detected as the plurality of spectrum peaks have been excluded; and an abnormality diagnosis section 22D which diagnoses that the rotary machine equipment 4 is abnormal in a case where the sum is equal to or greater than a first threshold. Thus, slight change in signal intensities due to slight torque variation is prevented from being buried among spectrum peaks, whereby detection accuracy for slight torque variation is improved, and as a result, abnormality due to a failure mode involving slight torque variation can be accurately diagnosed.

As described above, the abnormality diagnosis method of the present embodiment includes: a current signal detection step S1 of detecting a current signal of current flowing through an electric motor 5; a frequency analysis step S2 of performing frequency analysis on a waveform of the current signal detected in the current signal detection step S1; a feature frequency band extraction step S3 of extracting data belonging to a feature frequency band so as to include a plurality of spectrum peaks, in a predetermined frequency range in a frequency analysis result which is a result of the frequency analysis on the waveform of the current signal performed in the frequency analysis step S2; a data exclusion step S31 of detecting the plurality of spectrum peaks from the data belonging to the feature frequency band, and excluding data detected as the plurality of spectrum peaks from the data belonging to the feature frequency band; a feature quantity calculation step S41 of calculating a sum of signal intensities included in the data belonging to the feature frequency band from which the data detected as the plurality of spectrum peaks have been excluded; a determination step S4E of determining whether or not the sum is equal to or greater than a first threshold; and an abnormality diagnosis step S5 of diagnosing that the rotary machine equipment 4 is abnormal in a case where the sum is equal to or greater than the first threshold. Thus, slight change in signal intensities due to slight torque variation is prevented from being buried among spectrum peaks, whereby detection accuracy for slight torque variation is improved, and as a result, abnormality due to a failure mode involving slight torque variation can be accurately diagnosed.

As described above, the program of the present embodiment is a program for diagnosing abnormality in the rotary machine equipment 4 and causes a computer to execute: a current signal detection step S1 of detecting a current signal of current flowing through an electric motor 5; a frequency analysis step S2 of performing frequency analysis on a waveform of the current signal detected in the current signal detection step S1; a feature frequency band extraction step S3 of extracting data belonging to a feature frequency band so as to include a plurality of spectrum peaks, in a predetermined frequency range in a frequency analysis result which is a result of the frequency analysis on the waveform of the current signal performed in the frequency analysis step S2; a data exclusion step S31 of detecting the plurality of spectrum peaks from the data belonging to the feature frequency band, and excluding data detected as the plurality of spectrum peaks from the data belonging to the feature frequency band; a feature quantity calculation step S41 of calculating a sum of signal intensities included in the data belonging to the feature frequency band from which the data detected as the plurality of spectrum peaks have been excluded; a determination step S4E of determining whether or not the sum is equal to or greater than a first threshold; and an abnormality diagnosis step S5 of diagnosing that the rotary machine equipment 4 is abnormal in a case where the sum is equal to or greater than the first threshold. Thus, slight change in signal intensities due to slight torque variation is prevented from being buried among spectrum peaks, whereby detection accuracy for slight torque variation is improved, and as a result, abnormality due to a failure mode involving slight torque variation can be accurately diagnosed.

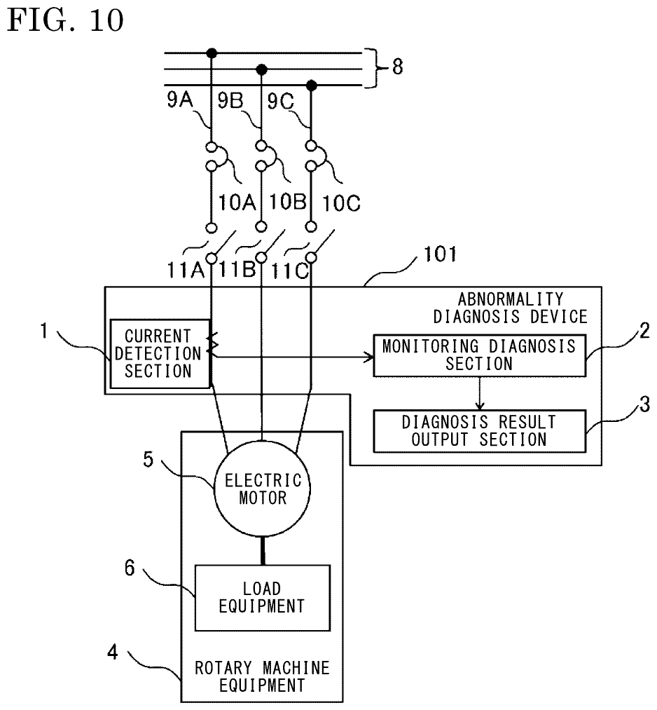

In the present embodiment, the example in which the electric motor 5 is driven by the inverter 7 has been shown. However, as shown in FIG. 10, the electric motor 5 may be connected to the commercial power supply 8 via a plurality of circuit breakers 10A, 10B, 10C and a plurality of electromagnetic contactors 11A, 11B, 11C, and may be driven by the commercial power supply 8.

In the present embodiment, the example in which the abnormality diagnosis device 101 includes the current detection section 1, the monitoring diagnosis section 2, and the diagnosis result output section 3, has been shown. However, the current detection section 1 and the diagnosis result output section 3 may be provided to an external device different from the abnormality diagnosis device 101.

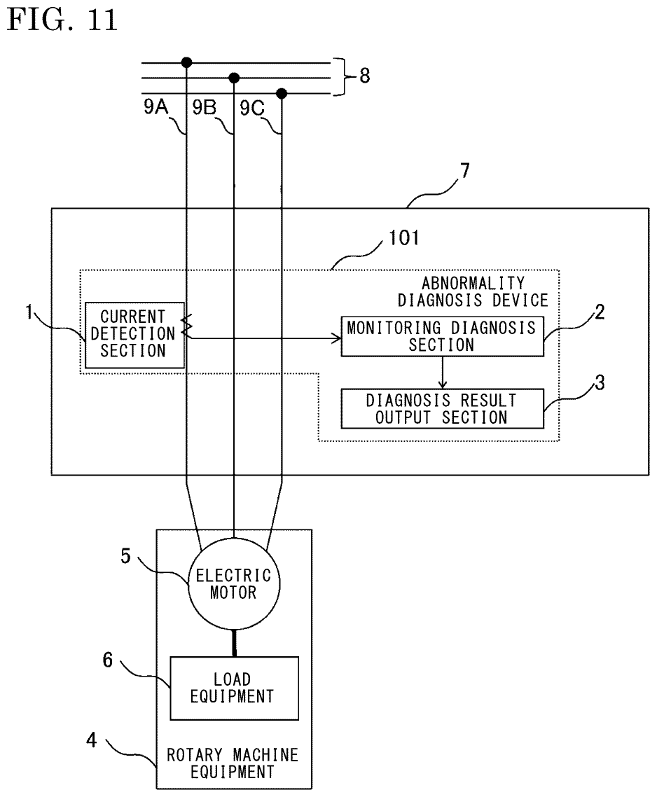

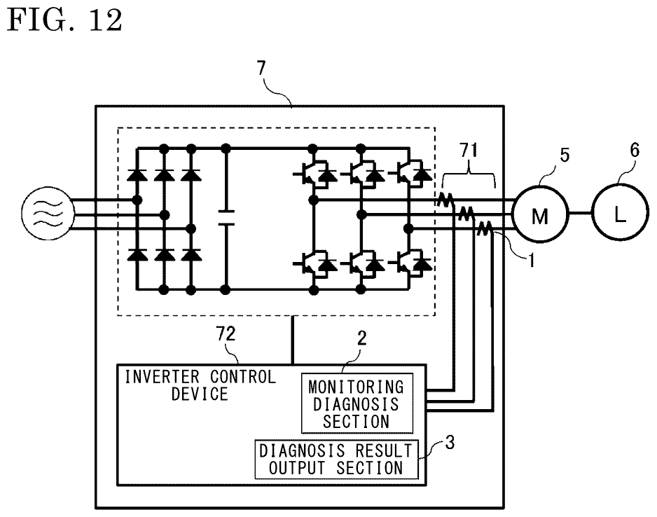

In the present embodiment, as shown in FIG. 11, the abnormality diagnosis device 101 may be configured such that at least one of the current detection section 1, the monitoring diagnosis section 2, and the diagnosis result output section 3 is provided to the inverter 7, by using a current detection section 71 for detecting current flowing through an AC bus of the electric motor 5 for the purpose of inverter control and an inverter control device 72 composed of a processor (CPU) and a memory, which are included in the inverter 7. FIG. 12 is a schematic diagram of a circuit representing the functional configuration shown in FIG. 11. In FIG. 12, an example in which all of the current detection section 1, the monitoring diagnosis section 2, and the diagnosis result output section 3 are provided to the inverter 7 is shown.

A hardware configuration of the inverter control device 72 is the same as the hardware configuration of the monitoring diagnosis section 2 shown in FIG. 4. The inverter control device 72 includes the transmission/reception device 23, the processor (central processing unit (CPU)) 24, the memory (read only memory (ROM)) 25, and the memory (random access memory (RAM)) 26. In the inverter control device 72, by the processor 24 executing a program stored in advance in the memory 25, three-phase/dq conversion is performed using information about current flowing through the electric motor 5 and an angle of the electric motor 5 detected by a rotational angle sensor (not shown) provided to the electric motor 5 in an output result from the current detection section 71, and a d-axis current detection value and a q-axis current detection value are detected and stored in the memory 26. These detection values are compared with a d-axis current command value and a q-axis current command value given from a host control device, whereby a d-axis voltage command value and a q-axis voltage command value are calculated. The calculated d-axis and q-axis voltage command values and rotational position information about the electric motor 5 are subjected to two-phase/three-phase conversion, and then the transmission/reception device 23 outputs voltage command values to windings of the electric motor 5. Using the processor 24 and the memories 25 and 26 of the inverter control device 72 as described above, the monitoring diagnosis section 2 and the diagnosis result output section 3 can be provided to the inverter control device 72. The current detection section 71 for one phase is used as the current detection section 1, a predetermined program is stored in the memory 25, and the processor 24 executes the program, whereby various function modules of the monitoring diagnosis section 2 are implemented.

In the present embodiment, the example in which the data belonging to the feature frequency band are extracted so as to include a plurality of spectrum peaks, in the frequency range from the zeroth-order component to the second-order component with respect to the power supply frequency, and abnormality diagnosis for the rotary machine equipment is performed using the extracted data belonging to the feature frequency band, has been shown. However, in a plurality of frequency ranges, respective sets of data belonging to the feature frequency bands may be extracted so as to each include a plurality of spectrum peaks, and abnormality diagnosis for the rotary machine equipment may be performed using the extracted respective sets of data belonging to the feature frequency bands.

For example, in the frequency range from the zeroth-order component to the second-order component with respect to the power supply frequency and the frequency range from the fourth-order component to the sixth-order component with respect to the power supply frequency, respective sets of data belonging to the feature frequencies may be extracted so as to each include a plurality of spectrum peaks, and abnormality diagnosis for the rotary machine equipment may be performed using the data belonging to the feature frequency band extracted in the frequency range from the zeroth-order component to the second-order component with respect to the power supply frequency and the data belonging to the feature frequency band extracted in the frequency range from the fourth-order component to the sixth-order component with respect to the power supply frequency.

In the present embodiment, the example in which the determination reference to be used in abnormality diagnosis is generated by repeatedly performing initial learning recording for accumulating calculated feature quantities in the determination reference storage section 21B during a predetermined period from the start of driving of the rotary machine equipment and then performing statistical processing on the accumulated feature quantities, has been shown. However, a predetermined determination reference may be set and stored in the determination reference storage section 21B in advance.

### Modification 1

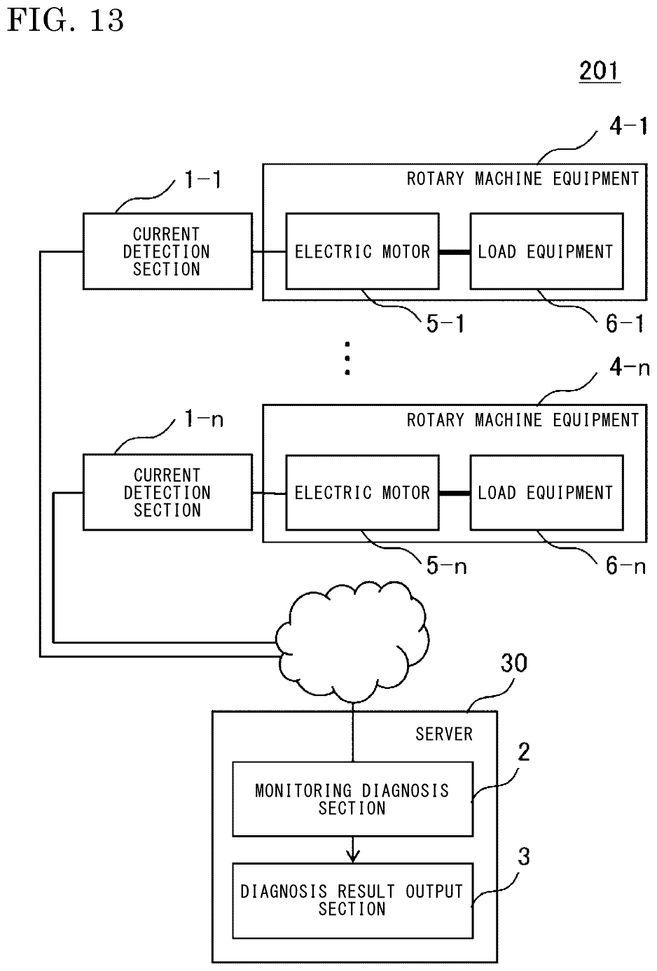

FIG. 13 shows an abnormality diagnosis system 201 according to modification 1 of embodiment 1. In the configuration example shown in FIG. 1, the abnormality diagnosis device 101 in which the current detection section 1, the monitoring diagnosis section 2, and the diagnosis result output section 3 are integrated, is provided, and the abnormality diagnosis device 101 performs abnormality diagnosis for the rotary machine equipment 4, whereas the abnormality diagnosis system 201 shown in FIG. 13 includes a server 30 including the monitoring diagnosis section 2 and the diagnosis result output section 3, and current detection sections 1-1 to 1-n connected to rotary machine equipment 4-1 to 4-n including electric motors 5-1 to 5-n and load equipment 6-1 to 6-n, and the current detection sections 1-1 to 1-n and the server 30 are connected via a network. Here, n is the number of sets of rotary machine equipment 4-1 to 4-n, and is an integer not less than 1. The current detection sections 1-1 to 1-n measure current signals from the respective sets of rotary machine equipment 4-1 to 4-n. In this case, the monitoring diagnosis section 2 of the abnormality diagnosis system 201 acquires the current signals from the current detection sections 1-1 to 1-n corresponding to the respective sets of rotary machine equipment 4-1 to 4-n, via the network. The other operations and configurations of the abnormality diagnosis system 201 are the same as those shown in embodiment 1.

Thus, the abnormality diagnosis system 201 shown in FIG. 13 according to the above modification provides an effect that it becomes unnecessary to provide the abnormality diagnosis device 101 for each set of rotary machine equipment 4-1 to 4-n.

The electric motors 5-1 to 5-n may be the same type of electric motors, or the types of at least one of them may be different from the others of the electric motors 5-1 to 5-n. The sets of load equipment 6-1 to 6-n may be the same kind of load equipment, or the kinds of at least one of them may be different from the other kinds.

As described above, the abnormality diagnosis system 201 of the present embodiment is an abnormality diagnosis system 201 for diagnosing abnormality in the rotary machine equipment 4 and includes: a current signal storage section 21A which stores a current signal of an electric motor 5; a frequency analysis section 22A which performs frequency analysis on a waveform of the current signal stored in the current signal storage section 21A; a feature frequency band extraction section 22B which extracts data belonging to a feature frequency band so as to include a plurality of spectrum peaks, in a predetermined frequency range in a frequency analysis result which is a result of the frequency analysis on the waveform of the current signal performed by the frequency analysis section 22A; a feature quantity calculation section 221C which detects the plurality of spectrum peaks from the data belonging to the feature frequency band, excludes data detected as the plurality of spectrum peaks from the data belonging to the feature frequency band, and calculates a sum of signal intensities included in the data belonging to the feature frequency band from which the data detected as the plurality of spectrum peaks have been excluded; and an abnormality diagnosis section 22D which diagnoses that the rotary machine equipment 4 is abnormal in a case where the sum is equal to or greater than a first threshold. Thus, slight change in signal intensities due to slight torque variation is prevented from being buried among spectrum peaks, whereby detection accuracy for slight torque variation is improved, and as a result, abnormality due to a failure mode involving slight torque variation can be accurately diagnosed. In addition, an effect that it becomes unnecessary to provide the abnormality diagnosis device 101 for each set of rotary machine equipment 4-1 to 4-n, is provided.

### Modification 2

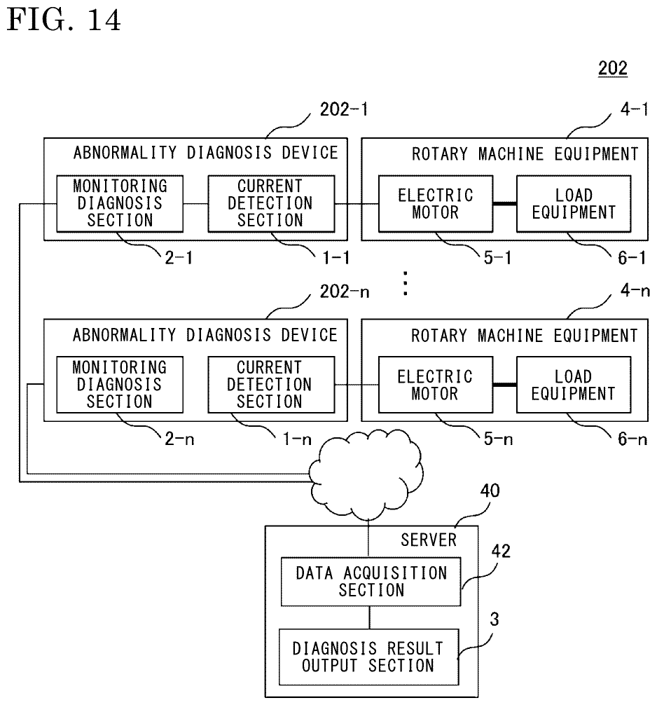

FIG. 14 shows an abnormality diagnosis system 202 according to modification 2 of embodiment 1. In the configuration example shown in FIG. 1, the abnormality diagnosis device 101 in which the current detection section 1, the monitoring diagnosis section 2, and the diagnosis result output section 3 are integrated, is provided, and the abnormality diagnosis device 101 performs abnormality diagnosis for the rotary machine equipment 4, whereas the abnormality diagnosis system 202 shown in FIG. 12 includes abnormality diagnosis devices 202-1 to 202-n including monitoring diagnosis sections 2-1 to 2-n and the current detection sections 1-1 to 1-n connected to the rotary machine equipment 4-1 to 4-n including the electric motors 5-1 to 5-n and the load equipment 6-1 to 6-n, and a server 40 including a data acquisition section 42 and the diagnosis result output section 3, and the abnormality diagnosis devices 202-1 to 202-n and the server 40 are connected via a network. In this case, the abnormality diagnosis devices 202-1 to 202-n transmit diagnosis results via the network, and the diagnosis result output section 3 of the server 40 acquires the diagnosis results from the abnormality diagnosis devices 202-1 to 202-n via the network. The other operations and configurations of the abnormality diagnosis system 202 are the same as those shown in embodiment 1.

As described above, the abnormality diagnosis system 202 shown in FIG. 14 in the present modification can collectively display the diagnosis results for the rotary machine equipment 4-1 to 4-n, thus facilitating comparison among the sets of rotary machine equipment 4-1 to 4-n, overall management thereof, and the like.

As described above, the abnormality diagnosis system 202 of the present embodiment is an abnormality diagnosis system 202 for diagnosing abnormality in the rotary machine equipment 4 and includes: a current signal storage section 21A which stores a current signal of an electric motor 5; a frequency analysis section 22A which performs frequency analysis on a waveform of the current signal stored in the current signal storage section 21A; a feature frequency band extraction section 22B which extracts data belonging to a feature frequency band so as to include a plurality of spectrum peaks, in a predetermined frequency range in a frequency analysis result which is a result of the frequency analysis on the waveform of the current signal performed by the frequency analysis section 22A; a feature quantity calculation section 221C which detects the plurality of spectrum peaks from the data belonging to the feature frequency band, excludes data detected as the plurality of spectrum peaks from the data belonging to the feature frequency band, and calculates a sum of signal intensities included in the data belonging to the feature frequency band from which the data detected as the plurality of spectrum peaks have been excluded; and an abnormality diagnosis section 22D which diagnoses that the rotary machine equipment 4 is abnormal in a case where the sum is equal to or greater than a first threshold. Thus, slight change in signal intensities due to slight torque variation is prevented from being buried among spectrum peaks, whereby detection accuracy for slight torque variation is improved, and as a result, abnormality due to a failure mode involving slight torque variation can be accurately diagnosed. In addition, the abnormality diagnosis system 202 can collectively display the diagnosis results for the rotary machine equipment 4-1 to 4-n, thus facilitating comparison among the sets of rotary machine equipment 4-1 to 4-n, overall management thereof, and the like.

### Embodiment 2

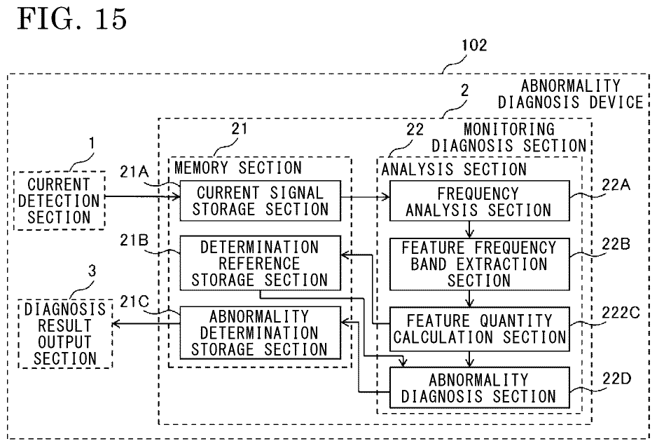

With reference to FIG. 15 to FIG. 18, an abnormality diagnosis device 102 according to the present embodiment will be described.

In embodiment 1, the configuration in which the sum of all signal intensities included in data belonging to the feature frequency band from which spectrum peaks have been excluded, is compared with the first threshold, whereby abnormality diagnosis for the rotary machine equipment 4 is performed, has been described. The present embodiment is different from embodiment 1 in that sorted data in which data belonging to the feature frequency band are sorted in the intensity order of signal intensities, are generated, and data of the signal intensities equal to or greater than a predetermined second threshold are excluded from the feature frequency band. The other configurations are the same as in embodiment 1, and parts that are the same as or correspond to those in embodiment 1 are denoted by the same reference characters.

Unlike the abnormality diagnosis device 101 of embodiment 1, in the abnormality diagnosis device 102 of the present embodiment, the monitoring diagnosis section 2 includes a feature quantity calculation section 222C instead of the feature quantity calculation section 221C, as shown in FIG. 15.

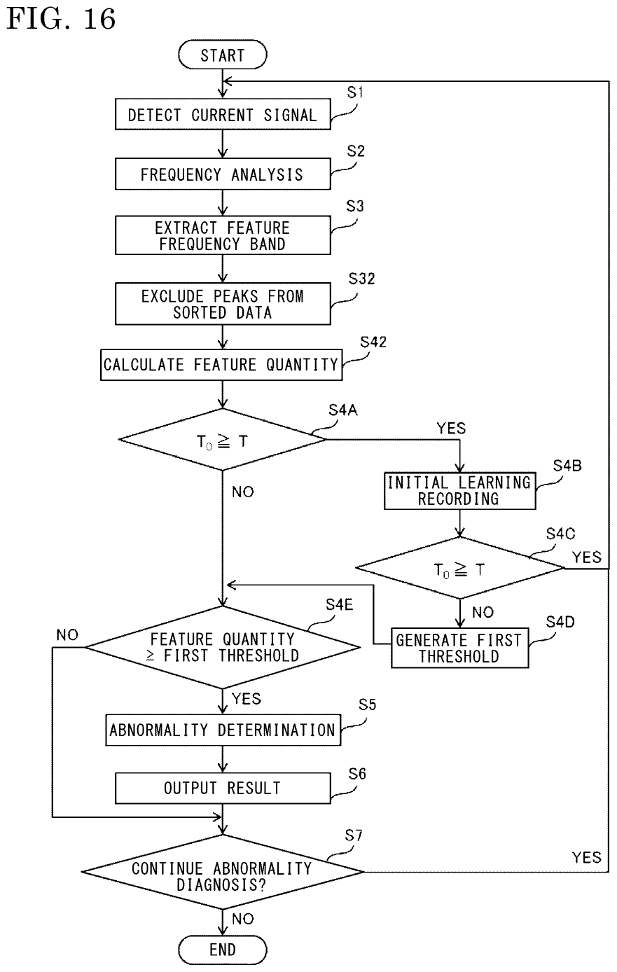

With reference to FIG. 16, a processing flow in the abnormality diagnosis device 102 according to the present embodiment will be described together with the detailed description of each component included in the abnormality diagnosis device 102. The process is the same as in embodiment 1 except for step S32 and step S42.

In step S32, the feature quantity calculation section 222C generates sorted data in which data belonging to the feature frequency band extracted by the feature frequency band extraction section 22B are sorted in the intensity order of signal intensities, and excludes data of signal intensities equal to or greater than the predetermined second threshold from the feature frequency band.

As an example of a method for determining the second threshold, a lowermost signal intensity among data belonging to the feature frequency band may be determined and then a value defined as (lowermost signal intensity+10 dB) may be used as the second threshold.

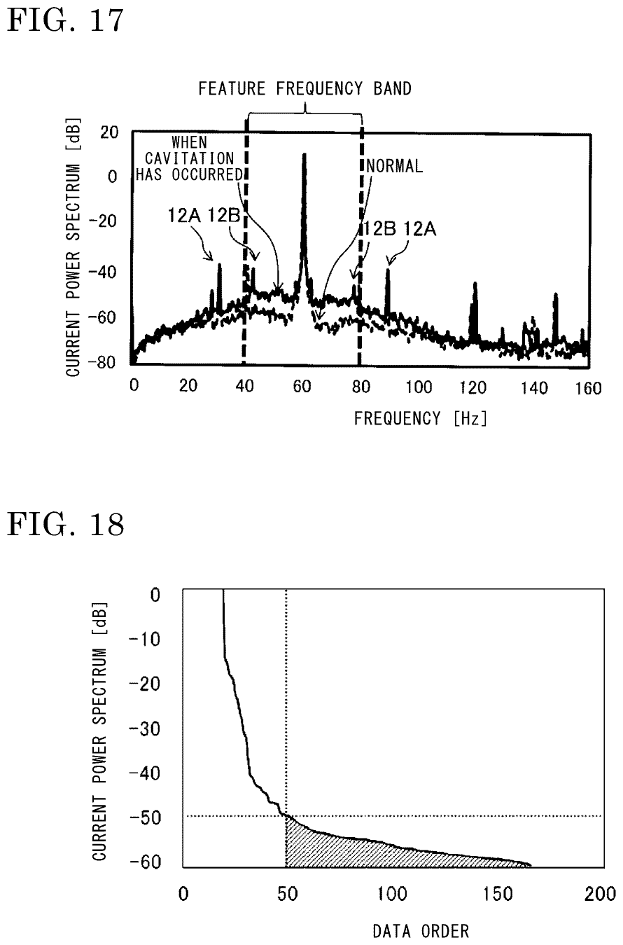

With reference to FIG. 17 and FIG. 18, a specific example of step S32 will be described.

FIG. 17 shows a case where data included in a frequency range of 120 Hz from the power supply frequency, i.e., a frequency range of 40 Hz to 80 Hz, are extracted as data belonging to the feature frequency band, in the graph in which frequency analysis results for current signals are compared, shown in FIG. 7. The vertical axis indicates a current power spectrum which is a kind of a signal intensity, and the horizontal axis indicates a frequency. In a case where the frequency analysis section 22A performs frequency analysis on the current signal with resolution of 0.25 Hz in step S2, the number of data belonging to the feature frequency band is 160, and the 160 data are sorted in the intensity order of signal intensities.

For example, in a case of using the aforementioned second threshold determination method, if the lowermost signal intensity is determined to be −60 dB in FIG. 17, the second threshold is −50 dB.

FIG. 18 shows sorted data in which 160 data in the feature frequency band shown in FIG. 17 are sorted in the intensity order of signal intensities from the left of the graph, i.e., 0, to the right of the graph, i.e., 160. The vertical axis indicates a current power spectrum which is a kind of a signal intensity, and the horizontal axis indicates a data order. In FIG. 18, as shown by a solid line, data order ranks are allocated to signal intensities in the intensity order. In addition, data of signal intensities (current power spectrum) greater than −50 dB which is the predetermined second threshold are excluded from the sorted data.

Then, in step S42 in FIG. 16, the feature quantity calculation section 222C calculates a feature quantity from the data belonging to the feature frequency band from which data of signal intensities greater than the second threshold have been excluded. In the present embodiment, the feature quantity corresponds to the sum of all signal intensities included in data belonging to the feature frequency band from which data of signal intensities equal to or greater than the second threshold have been excluded.

As described above, the abnormality diagnosis device 102 of the present embodiment generates sorted data in which data belonging to the feature frequency band are sorted in the intensity order of signal intensities, and excludes data of signal intensities equal to or greater than the predetermined second threshold from the data belonging to the feature frequency band. Then, the sum of all signal intensities included in data belonging to the feature frequency band from which data of signal intensities equal to or greater than the second threshold have been excluded is compared with the first threshold, whereby abnormality diagnosis for the rotary machine equipment 4 is performed. Thus, slight change in signal intensities due to slight torque variation is prevented from being buried among spectrum peaks, whereby detection accuracy for slight torque variation is improved, and as a result, abnormality due to a failure mode involving slight torque variation can be accurately diagnosed.

As described above, the abnormality diagnosis device 102 of the present embodiment is an abnormality diagnosis device 102 for diagnosing abnormality in the rotary machine equipment 4 and includes: a current signal storage section 21A which stores a current signal of an electric motor 5; a frequency analysis section 22A which performs frequency analysis on a waveform of the current signal stored in the current signal storage section 21A; a feature frequency band extraction section 22B which extracts data belonging to a feature frequency band so as to include a plurality of spectrum peaks, in a predetermined frequency range in a frequency analysis result which is a result of the frequency analysis on the waveform of the current signal performed by the frequency analysis section 22A; a feature quantity calculation section 222C which sorts the data belonging to the feature frequency band in an intensity order of signal intensities, excludes data of the signal intensities equal to or greater than a second threshold from the data belonging to the feature frequency band, and calculates a sum of the signal intensities included in the data belonging to the feature frequency band from which the data of the signal intensities equal to or greater than the second threshold have been excluded; and an abnormality diagnosis section 22D which diagnoses that the rotary machine equipment 4 is abnormal in a case where the sum is equal to or greater than a first threshold. Thus, slight change in signal intensities due to slight torque variation is prevented from being buried among spectrum peaks, whereby detection accuracy for slight torque variation is improved, and as a result, abnormality due to a failure mode involving slight torque variation can be accurately diagnosed.

As described above, the abnormality diagnosis method of the present embodiment is an abnormality diagnosis method for diagnosing abnormality in the rotary machine equipment 4 and includes: a current signal detection step S1 of detecting a current signal of current flowing through an electric motor 5; a frequency analysis step S2 of performing frequency analysis on a waveform of the current signal detected in the current signal detection step S1; a feature frequency band extraction step S3 of extracting data belonging to a feature frequency band so as to include a plurality of spectrum peaks, in a predetermined frequency range in a frequency analysis result which is a result of the frequency analysis on the waveform of the current signal performed in the frequency analysis step S2; a data exclusion step S32 of sorting the data belonging to the feature frequency band in an intensity order of signal intensities, and excluding data of the signal intensities equal to or greater than a second threshold from the data belonging to the feature frequency band; a feature quantity calculation step S42 of calculating a sum of the signal intensities included in the data belonging to the feature frequency band from which the data of the signal intensities equal to or greater than the second threshold have been excluded; a determination step S4E of determining whether or not the sum is equal to or greater than a first threshold; and an abnormality diagnosis step S5 of diagnosing that the rotary machine equipment 4 is abnormal in a case where the sum is equal to or greater than the first threshold. Thus, slight change in signal intensities due to slight torque variation is prevented from being buried among spectrum peaks, whereby detection accuracy for slight torque variation is improved, and as a result, abnormality due to a failure mode involving slight torque variation can be accurately diagnosed.

As described above, the program of the present embodiment is a program for diagnosing abnormality in the rotary machine equipment 4 and causes a computer to execute: a current signal detection step S1 of detecting a current signal of current flowing through an electric motor 5; a frequency analysis step S2 of performing frequency analysis on a waveform of the current signal detected in the current signal detection step S1; a feature frequency band extraction step S3 of extracting data belonging to a feature frequency band so as to include a plurality of spectrum peaks, in a predetermined frequency range in a frequency analysis result which is a result of the frequency analysis on the waveform of the current signal performed in the frequency analysis step S2; a data exclusion step S32 of detecting the plurality of spectrum peaks from the data belonging to the feature frequency band, and excluding data detected as the plurality of spectrum peaks from the data belonging to the feature frequency band; a feature quantity calculation step S42 of calculating a sum of signal intensities included in the data belonging to the feature frequency band from which the data detected as the plurality of spectrum peaks have been excluded; a determination step S4E of determining whether or not the sum is equal to or greater than a first threshold; and an abnormality diagnosis step S5 of diagnosing that the rotary machine equipment 4 is abnormal in a case where the sum is equal to or greater than the first threshold. Thus, slight change in signal intensities due to slight torque variation is prevented from being buried among spectrum peaks, whereby detection accuracy for slight torque variation is improved, and as a result, abnormality due to a failure mode involving slight torque variation can be accurately diagnosed.

### Modification 1

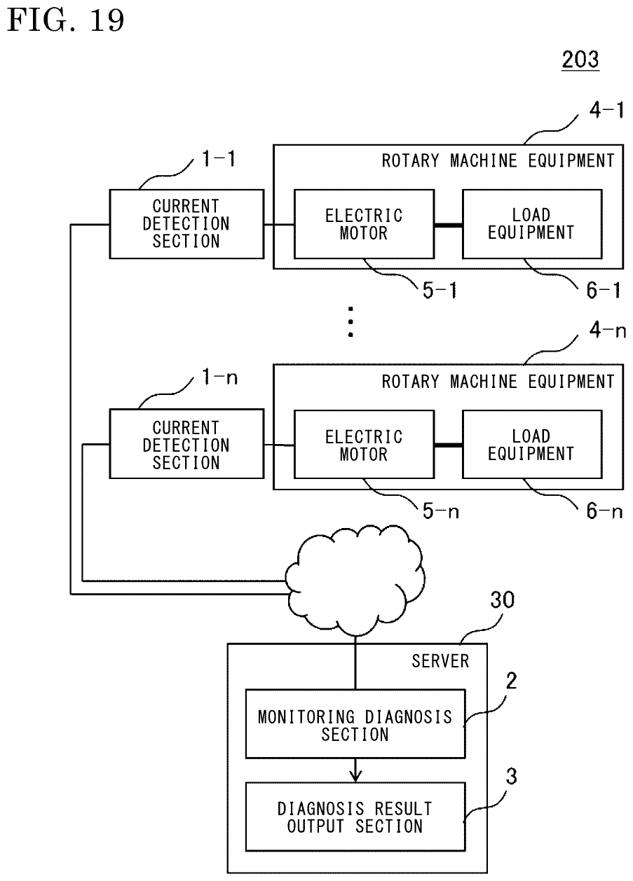

With reference to FIG. 19, an abnormality diagnosis system 203 according to modification 1 of embodiment 2 will be described.

In modification 1 of embodiment 1, the configuration in which the server 30 including the diagnosis result output section 3 and the monitoring diagnosis section 2 including the feature quantity calculation section 221C, and the current detection sections 1-1 to 1-n connected to the rotary machine equipment 4-1 to 4-n including the electric motors 5-1 to 5-n and the load equipment 6-1 to 6-n, are provided, has been described with reference to FIG. 13. The present modification is different from modification 1 of embodiment 1 in that the monitoring diagnosis section 2 is replaced with the monitoring diagnosis section 2 according to embodiment 2. The other configurations are the same as in modification 1 of embodiment 1, and parts that are the same as or correspond to those in modification 1 of embodiment 1 are denoted by the same reference characters.

Thus, the abnormality diagnosis system 203 shown in FIG. 19 in the above modification provides an effect that it becomes unnecessary to provide the abnormality diagnosis device 102 for each set of rotary machine equipment 4-1 to 4-n.

As described above, the abnormality diagnosis System 203 of the present embodiment is an abnormality diagnosis system 203 for diagnosing abnormality in the rotary machine equipment 4 and includes: a current signal storage section 21A which stores a current signal of an electric motor 5; a frequency analysis section 22A which performs frequency analysis on a waveform of the current signal stored in the current signal storage section 21A; a feature frequency band extraction section 22B which extracts data belonging to a feature frequency band so as to include a plurality of spectrum peaks, in a predetermined frequency range in a frequency analysis result which is a result of the frequency analysis on the waveform of the current signal performed by the frequency analysis section 22A; a feature quantity calculation section 222C which sorts the data belonging to the feature frequency band in an intensity order of signal intensities, excludes data of the signal intensities equal to or greater than a second threshold from the data belonging to the feature frequency band, and calculates a sum of the signal intensities included in the data belonging to the feature frequency band from which the data of the signal intensities equal to or greater than the second threshold have been excluded; and an abnormality diagnosis section 22D which diagnoses that the rotary machine equipment 4 is abnormal in a case where the sum is equal to or greater than a first threshold. Thus, slight change in signal intensities due to slight torque variation is prevented from being buried among spectrum peaks, whereby detection accuracy for slight torque variation is improved, and as a result, abnormality due to a failure mode involving slight torque variation can be accurately diagnosed. In addition, an effect that it becomes unnecessary to provide the abnormality diagnosis device 102 for each set of rotary machine equipment 4-1 to 4-n, is provided. In addition, the abnormality diagnosis system 202 can collectively display the diagnosis results for the rotary machine equipment 4-1 to 4-n, thus facilitating comparison among the sets of rotary machine equipment 4-1 to 4-n, overall management thereof, and the like.

### Modification 2

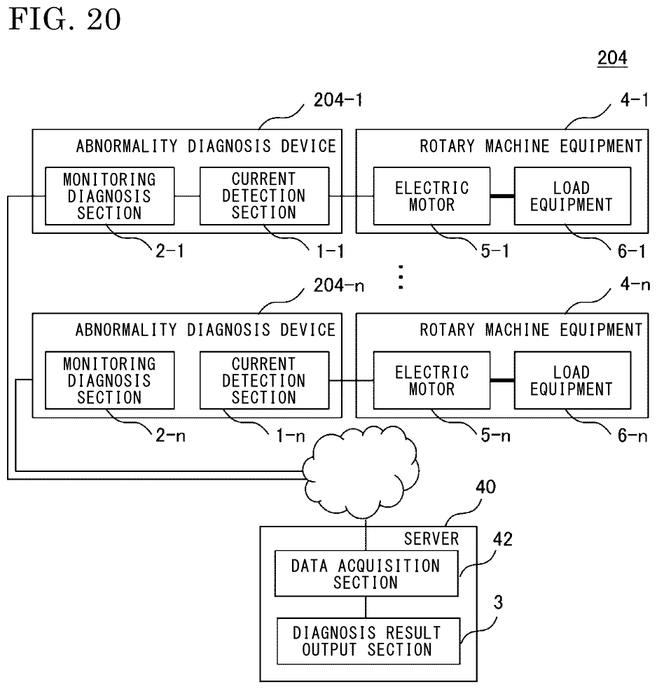

With reference to FIG. 20, an abnormality diagnosis system 204 according to modification 2 of the present embodiment will be described.

In modification 2 of embodiment 1, the configuration in which the abnormality diagnosis devices 202-1 to 202-n including the monitoring diagnosis sections 2-1 to 2-n and the current detection sections 1-1 to 1-n connected to the rotary machine equipment 4-1 to 4-n including the electric motors 5-1 to 5-n and the load equipment 6-1 to 6-n, and the server 40 including the data acquisition section 42 and the diagnosis result output section 3, are provided, has been described with reference to FIG. 14. The present modification is different from modification 2 of embodiment 1 in that the abnormality diagnosis device is replaced with abnormality diagnosis devices 204-1 to 204-n including the current detection sections 1-1 to 1-n and the monitoring diagnosis sections 2-1 to 2-n according to embodiment 2. The other configurations are the same as in modification 2 of embodiment 1, and parts that are the same as or correspond to those in modification 2 of embodiment 1 are denoted by the same reference characters.

As described above, the abnormality diagnosis system 204 shown in FIG. 20 in the present modification can collectively display the diagnosis results for the rotary machine equipment 4-1 to 4-n, thus facilitating comparison among the sets of rotary machine equipment 4-1 to 4-n, overall management thereof, and the like.

As described above, the abnormality diagnosis system 204 of the present embodiment is an abnormality diagnosis system 204 for diagnosing abnormality in the rotary machine equipment 4 and includes: a current signal storage section 21A which stores a current signal of an electric motor 5; a frequency analysis section 22A which performs frequency analysis on a waveform of the current signal stored in the current signal storage section 21A; a feature frequency band extraction section 22B which extracts data belonging to a feature frequency band so as to include a plurality of spectrum peaks, in a predetermined frequency range in a frequency analysis result which is a result of the frequency analysis on the waveform of the current signal performed by the frequency analysis section 22A; a feature quantity calculation section 222C which sorts the data belonging to the feature frequency band in an intensity order of signal intensities, excludes data of the signal intensities equal to or greater than a second threshold from the data belonging to the feature frequency band, and calculates a sum of the signal intensities included in the data belonging to the feature frequency band from which the data of the signal intensities equal to or greater than the second threshold have been excluded; and an abnormality diagnosis section 22D which diagnoses that the rotary machine equipment 4 is abnormal in a case where the sum is equal to or greater than a first threshold. Thus, slight change in signal intensities due to slight torque variation is prevented from being buried among spectrum peaks, whereby detection accuracy for slight torque variation is improved, and as a result, abnormality due to a failure mode involving slight torque variation can be accurately diagnosed. In addition, the abnormality diagnosis system 204 can collectively display the diagnosis results for the rotary machine equipment 4-1 to 4-n, thus facilitating comparison among the sets of rotary machine equipment 4-1 to 4-n, overall management thereof, and the like.

### Embodiment 3

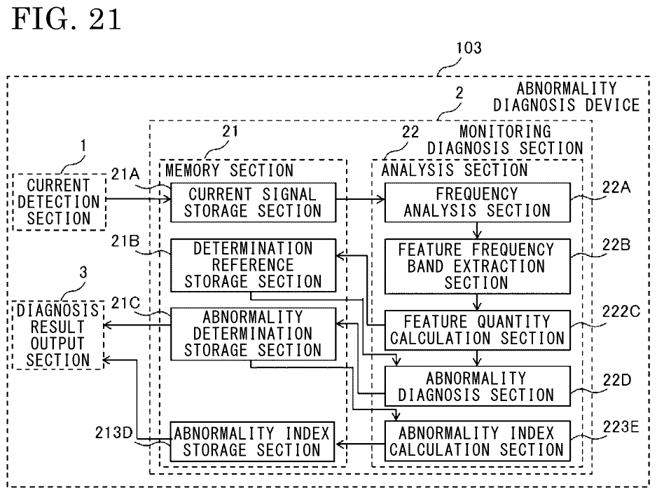

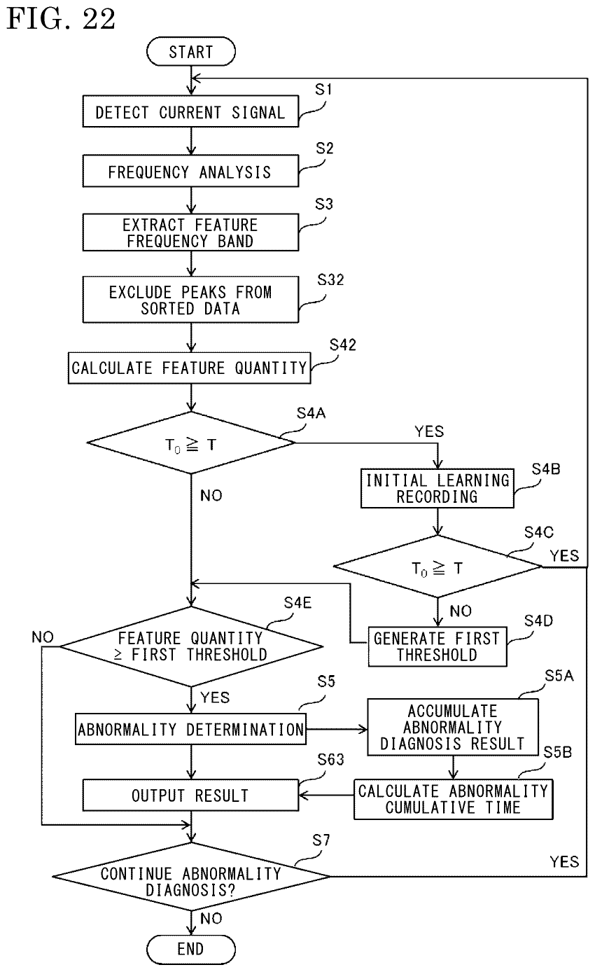

With reference to FIG. 21 and FIG. 22, an abnormality diagnosis device 103 according to the present embodiment will be described.

In embodiment 1 or 2, the configuration in which abnormality due to a failure mode involving slight torque variation is accurately diagnosed has been described. The present embodiment is different from embodiment 1 or 2 in that not only abnormality due to a failure mode involving slight torque variation is accurately diagnosed but also the total of operation times during which there is abnormality in the rotary machine equipment 4 is calculated. The other configurations are the same as in embodiment 1 or 2. As an example, a case of having the feature quantity calculation section 222C as in embodiment 2 will be described. Parts that are the same as or correspond to those in embodiment 1 or 2 are denoted by the same reference characters.

In the abnormality diagnosis device 103 of the present embodiment, as shown in FIG. 21, the monitoring diagnosis section 2 further includes an abnormality index storage section 213D and an abnormality index calculation section 223E, unlike the abnormality diagnosis device 101 of embodiment 1 or the abnormality diagnosis device 102 of embodiment 2.

With reference to FIG. 22, a processing flow in the abnormality diagnosis device 103 according to the present embodiment will be described together with the detailed description of each component included in the abnormality diagnosis device 103. The process is the same as in embodiment 1 or 2 except for step S5A, step S5B, and step S63, and steps that are the same as or correspond to those in embodiment 1 or 2 are denoted by the same reference characters.

In step S5A, the abnormality determination storage section 21C accumulates diagnosis results outputted from the abnormality diagnosis section 22D.

Then, in step S5B, using abnormality diagnosis results acquired from the abnormality determination storage section 21C, the abnormality index calculation section 223E calculates, as an abnormality cumulative time, the total of operation times during which there is abnormality in the rotary machine equipment 4, and outputs the abnormality cumulative time to the abnormality index storage section 213D.

Then, in step S63, the diagnosis result output section 3 acquires the abnormality cumulative time from the abnormality index storage section 213D. The diagnosis result output section 3 displays the abnormality cumulative time on the display section 31A such as a display, in addition to the diagnosis result acquired from the abnormality determination storage section 21C in embodiment 1 or 2, and the external output communication section 31C outputs the abnormality cumulative time to an external device such as a control device panel, a PC, or a cloud server, for example, to notify a monitoring person about the abnormality cumulative time, whereby tendency of the abnormality cumulative time is monitored.

As described above, the abnormality diagnosis device 103 of the present embodiment provides the effects of embodiment 1 or 2, and in addition, calculates the total of operation times during which there is abnormality in the rotary machine equipment 4, and notifies a monitoring person about the abnormality cumulative time during which there has been abnormality in the rotary machine equipment 4, together with the abnormality diagnosis result, whereby tendency of the abnormality cumulative time can be monitored. In addition, by comparing the abnormality cumulative times of a plurality of sets of rotary machine equipment 4, it is possible to utilize the abnormality cumulative times as useful indices for determining timings of maintenance and update of the rotary machine equipment 4.

In the present embodiment, the example in which the abnormality index calculation section 223E calculates the abnormality cumulative time has been shown. However, an external device different from the abnormality diagnosis device 103 may calculate the abnormality cumulative time.

### Embodiment 4

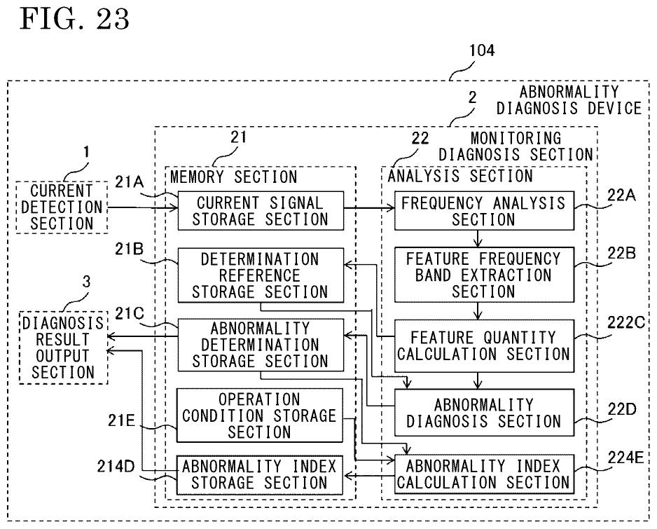

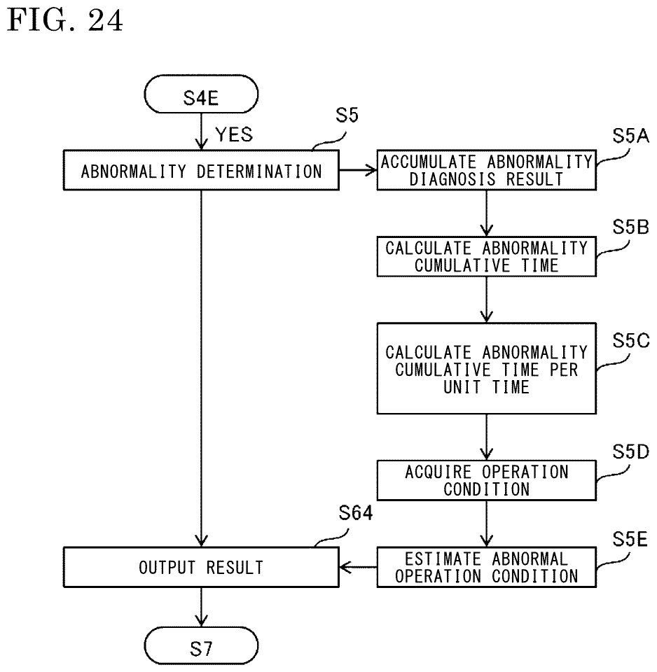

With reference to FIG. 23 and FIG. 24, an abnormality diagnosis device 104 according to the present embodiment will be described.

In embodiment 3, the configuration in which abnormality due to a failure mode involving slight torque variation is accurately diagnosed and the total of operation times during which there is abnormality in the rotary machine equipment 4 is calculated as the abnormality cumulative time, has been described. The present embodiment is different from embodiment 3 in that an operation condition of the rotary machine equipment 4 that causes abnormality is estimated. The other configurations are the same as in embodiment 3, and parts that are the same as or correspond to those in embodiment 3 are denoted by the same reference characters.

In the abnormality diagnosis device 104 of the present embodiment, as shown in FIG. 23, the monitoring diagnosis section 2 includes an abnormality index storage section 214D and an abnormality index calculation section 224E instead of the abnormality index storage section 213D and the abnormality index calculation section 223E, and further includes an operation condition storage section 21E, unlike the abnormality diagnosis device 103 of embodiment 3.

The operation condition storage section 21E stores time-by-time operation conditions of the rotary machine equipment 4. Examples of the operation conditions include the flow rate of water sent from a water pump which is the load equipment 6, the pressure of water sent from the water pump, and the opening degree of a valve of an input/output pipe through which water flows into or is discharged from the water pump, in a case of application to a public plant monitoring control system such as a water treatment plan.

With reference to FIG. 24, a processing flow in the abnormality diagnosis device 104 according to the present embodiment will be described together with the detailed description of each component included in the abnormality diagnosis device 104. The process is the same as in embodiment 3 except for step S5C, step S5D, step S5E, and step S64, and steps that are the same as or correspond to those in embodiment 3 are denoted by the same reference characters. FIG. 24 corresponds to a process to step S7 from a case where determination is made as YES in step S4E in the processing flow shown in FIG. 22, and only this range is taken and shown, for convenience of description.

In step S5C, using the abnormality cumulative time, the abnormality index calculation section 224E calculates an abnormality cumulative time per unit operation time of the rotary machine equipment 4 and an abnormality cumulative time per total operation time which is a third threshold.

Here, the abnormality cumulative time per unit operation time is the proportion of time during which there is abnormality in the rotary machine equipment 4 per unit operation, and the abnormality cumulative time per total operation time is the proportion of time during which there is abnormality in the rotary machine equipment 4, in the total operation time.

The abnormality cumulative time per unit operation time is calculated by dividing the total of operation times during which there is abnormality in the rotary machine equipment 4 per unit operation time, by the unit operation time.

The abnormality cumulative time per total operation time is calculated by dividing the total of operation times during which there is abnormality in the rotary machine equipment 4 from the start of driving of the rotary machine equipment 4 to the present, by an operation time from the start of driving of the rotary machine equipment 4 to the present.

Then, in step S5D, the abnormality index calculation section 224E compares the abnormality cumulative time per the unit operation time with the abnormality cumulative time per total operation time. If the abnormality cumulative time per unit operation time is equal to or greater than the abnormality cumulative time per total operation time, the abnormality index calculation section 224E acquires the operation condition of the rotary machine equipment 4 applied at that time, from the operation condition storage section 21E.

Then, in step S5E, if there is abnormality in the rotary machine equipment 4, the abnormality index calculation section 224E estimates the operation condition actually applied to the rotary machine equipment 4 at that time, as a cause for occurrence of abnormality. That is, using the operation condition acquired from the operation condition storage section 21E, the abnormality index calculation section 224E estimates the operation condition of the rotary machine equipment 4 that causes abnormality, as an abnormality causing operation condition. In addition, the abnormality index calculation section 224E outputs the abnormality causing operation condition to the abnormality index storage section 214D.

Then, in step S64, the diagnosis result output section 3 acquires the abnormality causing operation condition from the abnormality index storage section 214D. The diagnosis result output section 3 displays the abnormality causing operation condition on the display section 31A such as a display, in addition to the diagnosis result acquired from the abnormality determination storage section 21C in embodiment 1 or 2, and the external output communication section 31C outputs the abnormality causing operation condition to an external device such as a control device panel, a PC, or a cloud server, for example, to notify a monitoring person about the abnormality causing operation condition, whereby tendency of the abnormality causing operation condition is monitored.

As described above, the abnormality diagnosis device 104 of the present embodiment provides the effects of embodiment 1 or 2, and in addition, estimates the operation condition of the rotary machine equipment 4 that causes abnormality, and notifies a monitoring person about the operation condition of the rotary machine equipment 4 that causes abnormality, together with the abnormality diagnosis result, whereby tendency of the abnormality causing operation condition can be monitored. In addition, the estimated abnormality causing operation condition can be utilized as a useful index for determining the operation condition of the rotary machine equipment 4.

In the present embodiment, the example in which the abnormality index calculation section 224E calculates the abnormality causing operation condition has been shown. However, an external device different from the abnormality diagnosis device 104 may calculate the abnormality causing operation condition.

### Embodiment 5

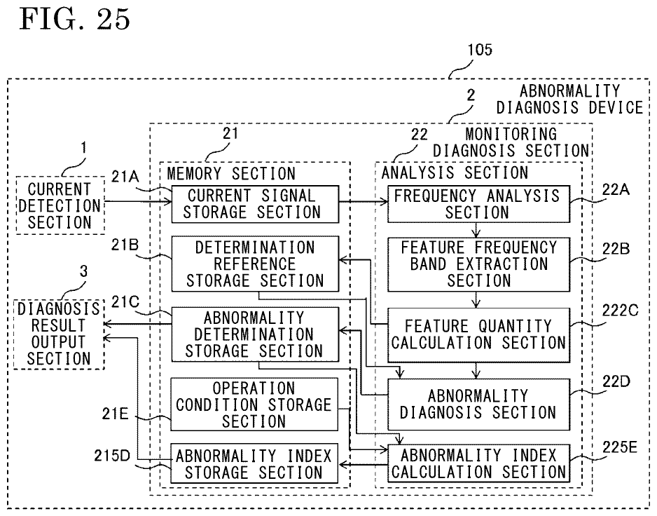

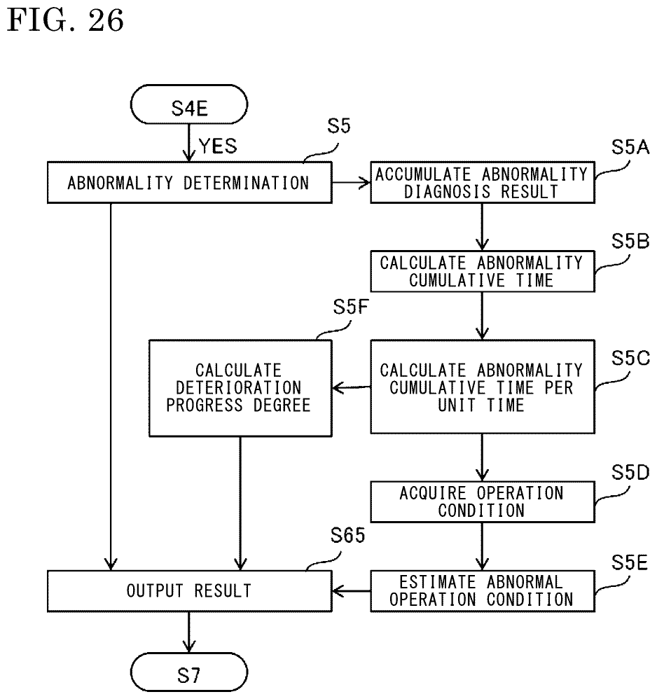

With reference to FIG. 25 and FIG. 26, an abnormality diagnosis device 105 according to the present embodiment will be described.

In embodiment 4, the configuration in which the operation condition of the rotary machine equipment 4 that causes abnormality is estimated has been described. The present embodiment is different from embodiment 4 in that a deterioration progress degree of the rotary machine equipment 4 is calculated. The other configurations are the same as in embodiment 4, and parts that are the same as or correspond to those in embodiment 4 are denoted by the same reference characters.

In the abnormality diagnosis device 105 of the present embodiment, as shown in FIG. 25, the monitoring diagnosis section 2 includes an abnormality index storage section 215D and an abnormality index calculation section 225E instead of the abnormality index storage section 214D and the abnormality index calculation section 224E, unlike the abnormality diagnosis device 104 of embodiment 4.

With reference to FIG. 26, a processing flow in the abnormality diagnosis device 105 according to the present embodiment will be described together with the detailed description of each component included in the abnormality diagnosis device 105. The process is the same as in embodiment 4 except for step S5F and step S65, and steps that are the same as or correspond to those in embodiment 4 are denoted by the same reference characters.

FIG. 26 corresponds to a process to step S7 from a case where determination is made as YES in step S4E in the processing flow shown in FIG. 22, and only this range is taken and shown, for convenience of description.

In step S5F, the abnormality index calculation section 225E calculates, as the deterioration progress degree of the rotary machine equipment 4, a product of the feature quantity calculated in step S41 or step S42 and the abnormality occurrence cumulative time calculated in step S5B, a product of the feature quantity calculated in step S41 or step S42 and the abnormality cumulative time per unit time in the rotary machine equipment 4 calculated in step S5C, or a product of the feature quantity calculated in step S41 or step S42 and the abnormality cumulative time per total operation time in the rotary machine equipment 4 calculated in step S5C.

Here, the deterioration progress degree is an index that indicates the progress degree of deterioration in the rotary machine equipment 4 caused due to abnormality in the rotary machine equipment 4.

Then, in step S65, the diagnosis result output section 3 acquires the deterioration progress degree from the abnormality index storage section 215D. The diagnosis result output section 3 displays the deterioration progress degree on the display section 31A such as a display, in addition to the diagnosis result acquired from the abnormality determination storage section 21C in embodiment 1 or 2, and the external output communication section 31C outputs the deterioration progress degree to an external device such as a control device panel, a PC, or a cloud server, for example, to notify a monitoring person about the deterioration progress degree, whereby tendency of the deterioration progress degree is monitored.

As described above, the abnormality diagnosis device 105 of the present embodiment provides the effects of embodiment 1 or 2, and in addition, calculates the deterioration progress degree and notifies a monitoring person about the deterioration progress degree, together with the abnormality diagnosis result, whereby tendency of the deterioration progress degree can be monitored. In addition, by comparing the deterioration progress degrees of a plurality of sets of rotary machine equipment 4, it is possible to utilize the deterioration progress degrees as useful indices for determining timings of maintenance and update of the rotary machine equipment 4.

In the present embodiment, the example in which the abnormality index calculation section 225E calculates the deterioration progress degree has been shown. However, an external device different from the abnormality diagnosis device 105 may calculate the deterioration progress degree.

### Embodiment 6

In embodiment 1 or 2, the configuration in which abnormality due to a failure mode involving slight torque variation is accurately diagnosed has been described. In embodiment 3, the configuration in which the total of operation times during which there is abnormality in the rotary machine equipment 4 is calculated as the abnormality cumulative time has been described. In embodiment 4, the configuration in which the operation condition of the rotary machine equipment 4 that causes abnormality is estimated has been described. In embodiment 5, the configuration in which the deterioration progress degree of the rotary machine equipment 4 is calculated has been described.

The present embodiment is different from embodiments 1 to 5 in that control is performed to make such an operation condition that inhibits deterioration progress, on the basis of abnormality detection or the abnormality cumulative time, the operation condition of the rotary machine equipment 4 that causes abnormality, or the deterioration progress degree of the rotary machine equipment 4.

For example, in a case where the rotary machine equipment 4 is pump equipment, cavitation occurs as a failure mode involving slight torque variation, as described above. Cavitation occurs as follows. When the flow speed of a liquid locally increases in the pump, the pressure is lowered, and then, when the pressure becomes lower than the Saturation vapor pressure of the liquid, the liquid is vaporized, thus causing cavitation. Further, sharp volume change when the vapor returns to the liquid causes a shock, which damages the pump. In order to suppress such cavitation, the rotational speed of the rotary machine equipment 4 is made smaller than that in the operation condition that causes cavitation, whereby the flow speed of the liquid is reduced.

Suppression of cavitation is merely an example. In embodiment 1 or 2, if abnormality is detected, the rotational speed of the rotary machine equipment 4 is subjected to feedback control, whereby occurrence of abnormality can be suppressed. Control for: suppressing occurrence of abnormality in accordance with the abnormality cumulative time calculated in embodiment 3 may be fed back to the rotary machine equipment 4. Control for suppressing occurrence of abnormality in accordance with the deterioration progress degree calculated in embodiment 5 may be fed back to the rotary machine equipment 4. Control for performing operation so as to avoid the operation condition of the rotary machine equipment 4 that causes abnormality, which is estimated in embodiment 4, may be fed back. In this case, the operation condition storage section for storing the operation condition of the rotary machine equipment needs to have stored therein the operation condition of the rotary machine equipment before it is diagnosed that there is abnormality.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 current detection section
2 monitoring diagnosis section
3 diagnosis result output section
4 rotary machine equipment
5 electric motor
6 load equipment
7 inverter
8 commercial power supply
101, 102, 103, 104, 105 abnormality diagnosis device

1-28. (canceled)

29. An abnormality diagnosis device for diagnosing abnormality in rotary machine equipment, the abnormality diagnosis device comprising:
a current signal storage circuitry which stores a current signal of an electric motor;
a frequency analysis circuitry which performs frequency analysis on a waveform of the current signal stored in the current signal storage circuitry;
a feature frequency band extraction circuitry which extracts data belonging to a feature frequency band so as to include a plurality of spectrum peaks, in a predetermined frequency range in a frequency analysis result which is a result of the frequency analysis on the waveform of the current signal performed by the frequency analysis circuitry;
a feature quantity calculation circuitry which detects the plurality of spectrum peaks from the data belonging to the feature frequency band, excludes data detected as the plurality of spectrum peaks from the data belonging to the feature frequency band, and calculates a sum of signal intensities included in the data belonging to the feature frequency band from which the data detected as the plurality of spectrum peaks have been excluded;
an abnormality diagnosis circuitry which diagnoses that the rotary machine equipment is abnormal in a case where the sum is equal to or greater than a first threshold; wherein
the first threshold is a value obtained by performing statistical processing on the sums accumulated during a predetermined period from start of driving of the rotary machine equipment; and
in a case where a number of data of the sum and a number of data of the first threshold are different from each other, the feature quantity calculation circuitry sequentially excludes data having higher signal intensities from data of the first threshold or sequentially excludes data having higher signal intensities from data of the sum, so that the number of data of the sum and the number of data of the first threshold coincide with each other.

30. An abnormality diagnosis device for diagnosing abnormality in rotary machine equipment, the abnormality diagnosis device comprising:
a current signal storage circuitry which stores a current signal of an electric motor;
a frequency analysis circuitry which performs frequency analysis on a waveform of the current signal stored in the current signal storage circuitry;
a feature frequency band extraction circuitry which extracts data belonging to a feature frequency band so as to include a plurality of spectrum peaks, in a predetermined frequency range in a frequency analysis result which is a result of the frequency analysis on the waveform of the current signal performed by the frequency analysis circuitry;
a feature quantity calculation circuitry which sorts the data belonging to the feature frequency band in an intensity order of signal intensities, excludes data of the signal intensities equal to or greater than a second threshold from the data belonging to the feature frequency band, and calculates a sum of the signal intensities included in the data belonging to the feature frequency band from which the data of the signal intensities equal to or greater than the second threshold have been excluded; and
an abnormality diagnosis circuitry which diagnoses that the rotary machine equipment is abnormal in a case where the sum is equal to or greater than a first threshold; wherein
the first threshold is a value obtained by performing statistical processing on the sums accumulated during a predetermined period from start of driving of the rotary machine equipment; and
in a case where a number of data of the sum and a number of data of the first threshold are different from each other, the feature quantity calculation circuitry sequentially excludes data having higher signal intensities from data of the first threshold or sequentially excludes data having higher signal intensities from data of the sum, so that the number of data of the sum and the number of data of the first threshold coincide with each other.

31. The abnormality diagnosis device according to claim 29, wherein
the signal intensities are current values or a current power spectrum of the current signal.

32. The abnormality diagnosis device according to claim 30, wherein
the signal intensities are current values or a current power spectrum of the current signal.

33. The abnormality diagnosis device according to claim 31, further comprising a current detection circuitry which is connected to a wire connecting the electric motor and a commercial power supply for supplying power to the electric motor, detects current for driving the electric motor, and outputs a current signal of the detected current to the current signal storage circuitry.

34. The abnormality diagnosis device according to claim 32, further comprising a current detection circuitry which is connected to a wire connecting the electric motor and a commercial power supply for supplying power to the electric motor, detects current for driving the electric motor, and outputs a current signal of the detected current to the current signal storage circuitry.

35. The abnormality diagnosis device according to claim 29, further comprising an operation condition storage circuitry which stores an operation condition of the rotary machine equipment, wherein
the rotary machine equipment is operated such that the operation condition of the rotary machine equipment applied when the rotary machine equipment has been diagnosed to be abnormal is avoided.

36. The abnormality diagnosis device according to claim 30, further comprising an operation condition storage circuitry which stores an operation condition of the rotary machine equipment, wherein
the rotary machine equipment is operated such that the operation condition of the rotary machine equipment applied when the rotary machine equipment has been diagnosed to be abnormal is avoided.

37. The abnormality diagnosis device according to claim 31, further comprising an abnormality determination storage circuitry which stores a diagnosis result from the abnormality diagnosis circuitry when the abnormality diagnosis circuitry has diagnosed that the rotary machine equipment is abnormal.

38. The abnormality diagnosis device according to claim 32, further comprising an abnormality determination storage circuitry which stores a diagnosis result from the abnormality diagnosis circuitry when the abnormality diagnosis circuitry has diagnosed that the rotary machine equipment is abnormal.

39. The abnormality diagnosis device according to claim 37, further comprising a diagnosis result output circuitry including at least one of a display which displays the diagnosis result, an alarm which issues an alarm when the rotary machine equipment is diagnosed to be abnormal, and an external output communication which transmits the diagnosis result to an external device.

40. The abnormality diagnosis device according to claim 38, further comprising a diagnosis result output circuitry including at least one of a display which displays the diagnosis result, an alarm which issues an alarm when the rotary machine equipment is diagnosed to be abnormal, and an external output communication which transmits the diagnosis result to an external device.

41. The abnormality diagnosis device according to claim 37, further comprising an abnormality index calculation circuitry which calculates an abnormality cumulative time which is a total of operation times during which there is abnormality in the rotary machine equipment, using the diagnosis result stored in the abnormality determination storage circuitry.

42. The abnormality diagnosis device according to claim 38, further comprising an abnormality index calculation circuitry which calculates an abnormality cumulative time which is a total of operation times during which there is abnormality in the rotary machine equipment, using the diagnosis result stored in the abnormality determination storage circuitry.

43. The abnormality diagnosis device according to claim 37, further comprising an operation condition storage circuitry which stores an operation condition of the rotary machine equipment, wherein
the abnormality index calculation circuitry calculates the abnormality cumulative time per unit operation time of the rotary machine equipment, and in a case where the abnormality cumulative time per unit operation time of the rotary machine equipment is equal to or greater than a third threshold, the abnormality index calculation circuitry estimates the operation condition of the rotary machine equipment applied at that time, as an abnormality causing operation condition that causes abnormality in the rotary machine equipment.

44. The abnormality diagnosis device according to claim 38, further comprising an operation condition storage circuitry which stores an operation condition of the rotary machine equipment, wherein
the abnormality index calculation circuitry calculates the abnormality cumulative time per unit operation time of the rotary machine equipment, and in a case where the abnormality cumulative time per unit operation time of the rotary machine equipment is equal to or greater than a third threshold, the abnormality index calculation circuitry estimates the operation condition of the rotary machine equipment applied at that time, as an abnormality causing operation condition that causes abnormality in the rotary machine equipment.

45. The abnormality diagnosis device according to claim 41, wherein
the abnormality index calculation circuitry calculates the abnormality cumulative time per total operation time of the rotary machine equipment, and calculates a deterioration progress degree which is a product of the sum and the abnormality cumulative time, a product of the sum and the abnormality cumulative time per unit operation time of the rotary machine equipment, or a product of the sum and the abnormality cumulative time per total operation time of the rotary machine equipment.

46. The abnormality diagnosis device according to claim 42, wherein
the abnormality index calculation circuitry calculates the abnormality cumulative time per total operation time of the rotary machine equipment, and calculates a deterioration progress degree which is a product of the sum and the abnormality cumulative time, a product of the sum and the abnormality cumulative time per unit operation time of the rotary machine equipment, or a product of the sum and the abnormality cumulative time per total operation time of the rotary machine equipment.

47. The abnormality diagnosis device according to claim 45, further comprising an operation condition storage circuitry which stores an operation condition of the rotary machine equipment, wherein
the rotary machine equipment is operated such that the operation condition applied when the rotary machine equipment has been diagnosed to be abnormal is avoided, in accordance with the deterioration progress degree.

48. The abnormality diagnosis device according to claim 46, further comprising an operation condition storage circuitry which stores an operation condition of the rotary machine equipment, wherein
the rotary machine equipment is operated such that the operation condition applied when the rotary machine equipment has been diagnosed to be abnormal is avoided, in accordance with the deterioration progress degree.

49. An abnormality diagnosis method for diagnosing abnormality in rotary machine equipment, the abnormality diagnosis method comprising:
a current signal detection step of detecting a current signal of current flowing through an electric motor;
a frequency analysis step of performing frequency analysis on a waveform of the current signal detected in the current signal detection step;
a feature frequency band extraction step of extracting data belonging to a feature frequency band so as to include a plurality of spectrum peaks, in a predetermined frequency range in a frequency analysis result which is a result of the frequency analysis on the waveform of the current signal performed in the frequency analysis step;
a data exclusion step of detecting the plurality of spectrum peaks from the data belonging to the feature frequency band, and excluding data detected as the plurality of spectrum peaks from the data belonging to the feature frequency band;
a feature quantity calculation step of calculating a sum of signal intensities included in the data belonging to the feature frequency band from which the data detected as the plurality of spectrum peaks have been excluded;
a determination step of determining whether or not the sum is equal to or greater than a first threshold; and
an abnormality diagnosis step of diagnosing that the rotary machine equipment is abnormal in a case where the sum is equal to or greater than the first threshold; wherein
the first threshold is a value obtained by performing statistical processing on the sums accumulated during a predetermined period from start of driving of the rotary machine equipment; and
in a case where a number of data of the sum and a number of data of the first threshold are different from each other, the feature quantity calculation step sequentially excludes data having higher signal intensities from data of the first threshold or sequentially excludes data having higher signal intensities from data of the sum, so that the number of data of the sum and the number of data of the first threshold coincide with each other.

50. An abnormality diagnosis method for diagnosing abnormality in rotary machine equipment, the abnormality diagnosis method comprising:
a current signal detection step of detecting a current signal of current flowing through an electric motor;
a frequency analysis step of performing frequency analysis on a waveform of the current signal detected in the current signal detection step;
a feature frequency band extraction step of extracting data belonging to a feature frequency band so as to include a plurality of spectrum peaks, in a predetermined frequency range in a frequency analysis result which is a result of the frequency analysis on the waveform of the current signal performed in the frequency analysis step;
a data exclusion step of sorting the data belonging to the feature frequency band in an intensity order of signal intensities, and excluding data of the signal intensities equal to or greater than a second threshold from the data belonging to the feature frequency band;
a feature quantity calculation step of calculating a sum of the signal intensities included in the data belonging to the feature frequency band from which the data of the signal intensities equal to or greater than the second threshold have been excluded;
a determination step of determining whether or not the sum is equal to or greater than a first threshold; and
an abnormality diagnosis step of diagnosing that the rotary machine equipment is abnormal in a case where the sum is equal to or greater than the first threshold; wherein
the first threshold is a value obtained by performing statistical processing on the sums accumulated during a predetermined period from start of driving of the rotary machine equipment; and
in a case where a number of data of the sum and a number of data of the first threshold are different from each other, the feature quantity calculation step sequentially excludes data having higher signal intensities from data of the first threshold or sequentially excludes data having higher signal intensities from data of the sum, so that the number of data of the sum and the number of data of the first threshold coincide with each other.
